(19) United States
(12) Patent Application Publication
(10) Pub. No.: US 2025/0118946 A1
(43) Pub. Date: Apr. 10, 2025

(54) SEMICONDUCTOR LASER ELEMENT

(71) Applicant: Panasonic Holdings Corporation, Osaka (JP)

(72) Inventors: ATSUNORI MOCHIDA, Osaka (JP); HIROSHI OHNO, Osaka (JP)

(21) Appl. No.: 18/983,467

(22) Filed: Dec. 17, 2024

Related U.S. Application Data
(63) Continuation of application No. PCT/JP2023/022238, filed on Jun. 15, 2023.

(30) Foreign Application Priority Data
Jun. 28, 2022 (JP) 2022-103815

(51) Int. Cl. H01S 5/028

(52) U.S. Cl. CPC H01S 5/0287

(57) ABSTRACT

A semiconductor laser element includes a semiconductor stack body that emits a laser beam, an emission side protective layer that is disposed on a laser beam emission side end surface of the semiconductor stack body, and has a first end surface through which the laser beam travels; and a non-emission side protective layer that is disposed on a non-emission side end surface of the semiconductor stack body opposite to the laser beam emission side end surface and reflects the laser beam. A reflectivity at an oscillation wavelength of the laser beam in the emission side protective layer before an oxide containing silicon adheres to the first end surface is higher than a reflectivity at an oscillation wavelength of the laser beam in the emission side protective layer after the oxide adheres to the first end surface.

### TECHNICAL FIELD The present disclosure relates to a semiconductor laser element.

### BACKGROUND ART

As one of processing techniques for processing materials such as metal, wood, and synthetic resin, there is a laser processing technique. In order to expand the application of the laser processing technique, a laser beam is required to have higher power. A method using a semiconductor laser element (that is, a laser array element) having a plurality of luminous points as a light source has been proposed as one method for achieving higher power and a narrower beam of the laser beam.

In this method, a synthesis optical system that synthesizes a plurality of laser beams from the semiconductor laser element is constructed, and an external resonator is formed by the semiconductor laser element and a mirror disposed apart from the semiconductor laser element. As described above, the synthesis optical system is disposed in such an external resonator, and thus, a laser device that emits a laser beam having high quality such as higher power and a narrower beam can be realized.

In a laser device of an external resonator type, for example, in order to increase resonance efficiency of the laser beam by the external resonator, it is important to suppress resonance (so-called internal resonance) of the laser beam in the semiconductor laser element. Thus, in the semiconductor laser element used in the laser device of the external resonator type, it is required to realize a low reflectivity at an emission side end surface of the laser beam and to maintain the low reflectivity for a long period of time.

Note that, PTL 1 discloses a multi-wavelength semiconductor laser including a plurality of end surface emission type semiconductor light emitting units having different emission wavelengths.

### CITATION LIST

### Patent Literature

PTL 1: Unexamined Japanese Patent Publication No. 2010-219436

### SUMMARY OF THE INVENTION

A semiconductor laser element according to an exemplary embodiment of the present disclosure includes a semiconductor stack body that emits a laser beam, an emission side protective layer that is disposed on a laser beam emission side end surface of the semiconductor stack body and has a first end surface through which the laser beam travels, and a non-emission side protective layer that is disposed on a non-emission side end surface of the semiconductor stack body opposite to the laser beam emission side end surface and reflects the laser beam. A reflectivity at an oscillation wavelength of the laser beam in the emission side protective layer before an oxide containing silicon adheres to the first end surface is higher than a reflectivity at an oscillation wavelength of the laser beam in the emission side protective layer after the oxide adheres to the first end surface.

A laser device according to an exemplary embodiment of the present disclosure includes a semiconductor laser element including a semiconductor stack body that emits a laser beam, an emission side protective layer that is disposed on a laser beam emission side end surface of the semiconductor stack body and has a first end surface through which the laser beam travels, and a non-emission side protective layer that is disposed on a non-emission side end surface of the semiconductor stack body opposite to the laser beam emission side end surface and reflects the laser beam. A reflectivity at an oscillation wavelength of the laser beam in the emission side protective layer before an oxide containing silicon adheres to the first end surface is higher than a reflectivity at an oscillation wavelength of the laser beam in the emission side protective layer after the oxide adheres to the first end surface. The laser device further includes an accommodation unit that includes an intake port and an exhaust port and accommodates the semiconductor laser element, and a filter that adsorbs siloxane provided in the intake port.

### BRIEF DESCRIPTION OF THE DRAWINGS

FIG. 1 is a schematic sectional view illustrating a configuration example of a semiconductor laser element according to a first exemplary embodiment.

FIG. 2A is a graph representing wavelength dependency of an end surface reflectivity of the semiconductor laser element according to the first exemplary embodiment.

FIG. 2B is a graph representing the wavelength dependency of the end surface reflectivity of the semiconductor laser element according to the first exemplary embodiment.

FIG. 3 is a graph representing wavelength dependency of the end surface reflectivity of the semiconductor laser element.

FIG. 4 is a diagram illustrating an example of a relationship between an end surface reflectivity on a front side and an operating current value.

FIG. 5 is a diagram illustrating a configuration example of a laser device including the semiconductor laser element.

FIG. 6 is a diagram illustrating a configuration example of an optical system including the semiconductor laser element.

FIG. 7 is a schematic sectional view illustrating a configuration example of a semiconductor laser element according to a second exemplary embodiment.

FIG. 8A is a graph representing wavelength dependency of an end surface reflectivity of the semiconductor laser element according to the second exemplary embodiment.

FIG. 8B is a graph representing the wavelength dependency of the end surface reflectivity of the semiconductor laser element according to the second exemplary embodiment.

FIG. 9A is a graph representing wavelength dependency of an end surface reflectivity of a semiconductor laser element according to a third exemplary embodiment.

FIG. 9B is a graph representing the wavelength dependency of the end surface reflectivity of the semiconductor laser element according to the third exemplary embodiment.

FIG. 10A is a graph representing wavelength dependency of an end surface reflectivity of a semiconductor laser element according to a fourth exemplary embodiment.

FIG. 10B is a graph representing the wavelength dependency of the end surface reflectivity of the semiconductor laser element according to the fourth exemplary embodiment.

### DESCRIPTION OF EMBODIMENT

For example, a siloxane-derived SiOₓ contained in an atmosphere may be deposited on an emission side end surface of a laser beam of a semiconductor laser element by emission of the laser beam. When SiOₓ is deposited, a reflectivity of the emission side end surface of the semiconductor laser element changes, and a low reflectivity may not be maintained.

Non-limiting examples of the present disclosure contribute to providing a semiconductor laser element capable of maintaining a low reflectivity for a long period of time.

Hereinafter, exemplary embodiments of the present disclosure will be described with reference to the drawings. Note that, each exemplary embodiment to be described below illustrates one specific example of the present disclosure. Accordingly, numerical values, shapes, materials, components, arrangement positions and connection forms of the components, and the like illustrated in the following exemplary embodiments are merely examples, and are not intended to limit the present disclosure. In addition, the drawings are schematic views and are not necessarily strictly illustrated. Accordingly, scales and the like are not necessarily matched in the respective drawings.

Note that, in each drawing, substantially the same components are denoted by the same reference marks, and redundant description will be omitted or simplified. In addition, in the present description, the terms “upward” and “downward” do not refer to an upward direction (vertically upward) and a downward direction (vertically downward) in absolute space recognition, but are used as terms defined by a relative positional relationship based on a stacking order in a stacking configuration. In addition, the terms “upward” and “downward” are not only applied to a case where two components are spaced apart from each other and another component is present between the two components, but are also applied to a case where two components are disposed in close contact with each other.

### First Exemplary Embodiment

In a laser device of an external resonator type, a synthesis optical system that synthesizes a plurality of laser beams emitted from a semiconductor laser element is constructed. Examples of a method for synthesizing a plurality of laser beams include a spatial synthesis method for spatially synthesizing a plurality of laser beams and a wavelength synthesis method for converging a plurality of laser beams having different wavelengths from each other on the same optical axis. In order to realize narrowing of a beam by synthesizing a plurality of laser beams, the wavelength synthesis method for converging the plurality of laser beams on the same optical axis is more preferable than the spatial synthesis method in which a plurality of optical axes are different from each other.

In the wavelength synthesis method, for example, a laser array element can be used as the semiconductor laser element in order to generate the plurality of laser beams having different wavelengths. In the wavelength synthesis method, a plurality of laser array elements may be used to generate a large number of laser beams. The laser array element may be referred to as a semiconductor laser array element.

### 1-1. Overall Configuration Example

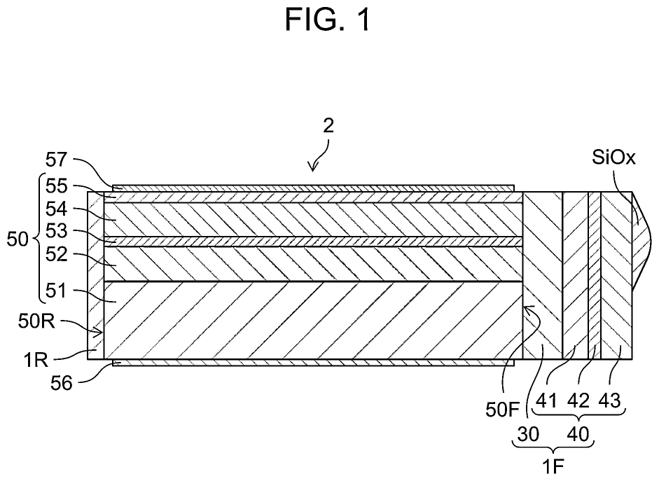

FIG. 1 is a schematic sectional view illustrating a configuration example of semiconductor laser element 2 according to the first exemplary embodiment. FIG. 1 illustrates a section along a stacking direction (vertical direction in FIG. 1) of semiconductor stack body 50 included in semiconductor laser element 2 and a resonance direction (horizontal direction in FIG. 1) of a laser beam. As illustrated in FIG. 1, semiconductor laser element 2 includes semiconductor stack body 50, end surface protective films 1F, end surface protective film 1R, first electrode 56, and second electrode 57.

Hereinafter, end surface protective film 1F side of semiconductor laser element 2 from which the laser beam is emitted may be referred to as a “front side”, and end surface protective film 1R side opposite to end surface protective film 1F may be referred to as a “rear side”.

Semiconductor laser element 2 is a semiconductor light emitting element that emits a plurality of laser beams. Semiconductor laser element 2 is, for example, a semiconductor laser element that outputs a blue laser beam in a band of 390 nm to 480 nm or a semiconductor laser element that outputs a green laser beam in a band of 480 nm to 530 nm. The laser beam is output from a front end surface of end surface protective film 1F. Semiconductor laser element 2 may be referred to as a laser array element or a laser bar.

In a blue-violet-based to green semiconductor laser element 2, for example, in a case where airtight sealing is not performed, siloxane-derived SiOₓ may be deposited on end surface protective film 1F on the front side by an operation of a semiconductor laser (the emission of the laser beam). For example, in the case of a short-wavelength laser such as blue, blue-violet, or ultraviolet, since an energy of the laser beam is high, a low-molecular siloxane floating in the air reacts with oxygen by a photochemical reaction by the laser beam, and is deposited in the form of SiOₓ. Similarly, SiOₓ may be deposited in the case of a green laser beam.

### 1-1-1. Configuration Examples of Semiconductor Stack Body and Electrode

Semiconductor stack body 50 is a stack body in which a plurality of semiconductor layers constituting semiconductor laser element 2 are stacked. As illustrated in FIG. 1, semiconductor stack body 50 has resonator end surface 50F and resonator end surface 50R facing resonator end surface 50F. End surface protective film 1F and end surface protective film 1R are disposed on resonator end surface 50F and resonator end surface 50R, respectively.

Semiconductor stack body 50 includes substrate 51, first semiconductor layer 52, active layer 53, second semiconductor layer 54, and contact layer 55. Semiconductor stack body 50 is made of, for example, a gallium nitride-based material. In a case where semiconductor stack body 50 is made of a gallium nitride-based material, semiconductor laser element 2 can emit the laser beam in a wavelength range of, for example, from about 390 nm to 530 nm inclusive.

Substrate 51 is a plate-shaped member serving as a base material of semiconductor stack body 50. Substrate 51 is, for example, a GaN single crystal substrate having a thickness of about 100 μm. A thickness of substrate 51 is not limited to 100 μm, and may range, for example, from 50 μm to 120 μm inclusive. In addition, the material for forming substrate 51 is not limited to GaN single crystal, and may be sapphire, SiC, GaAs, InP, Si, or the like.

First semiconductor layer 52 is a semiconductor layer of a first conductivity type disposed above substrate 51. First semiconductor layer 52 is an n-type semiconductor layer disposed on one principal surface of substrate 51, and includes an n-type cladding layer. The n-type cladding layer is a layer having a thickness of 1 μm and containing n-Al_{0.2}Ga_{0.8}N.

Note that, the configuration of the n-type cladding layer is not limited thereto. A thickness of the n-type cladding layer may be more than or equal to 0.5 μm, and a composition may be n-AlₓGa₁₋ₓN (0<x<1).

In addition, an n-type AlₓIn_{y}Ga_{1-x-y}N (0≤x+y≤1) guide layer or an undoped AlₓIn_{y}Ga_{1-x-y}N (0≤x+y≤1) guide layer may be provided on the n-type cladding layer.

Active layer 53 is a light emitting layer disposed above first semiconductor layer 52. For example, active layer 53 is a quantum well active layer in which well layers each containing In_{0.18}Ga_{0.82}N and having a thickness of 5 nm and barrier layers each containing GaN and having a thickness of 10 nm are alternately stacked, and has two well layers. Such active layer 53 is provided, and thus, semiconductor laser element 2 can emit a blue laser beam having a wavelength of about 440 nm. The configuration of active layer 53 is not limited thereto, and the p-type cladding layer may be a quantum well active layer obtained by alternately stacking well layers each containing InₓGa₁₋ₓN (0<x<1) and barrier layers each containing AlₓIn_{y}Ga_{1-x-y}N (0≤x+y≤1).

Note that, active layer 53 may include a guide layer formed at least one of above and below the quantum well active layer. In the above example, the number of well layers is two, but may be from one to four inclusive. In addition, the In composition of the well layer may be appropriately selected such that light having, of wavelengths ranging from 390 nm to 530 nm inclusive, a desired wavelength can be generated.

Second semiconductor layer 54 is a semiconductor layer of a second conductivity type disposed above active layer 53. The second conductivity type is a different conductivity type from the first conductivity type. For example, second semiconductor layer 54 is a p-type semiconductor layer and includes a p-type cladding layer. The p-type cladding layer is, for example, a superlattice layer in which 100 layers each containing p-Al_{0.2}Ga_{0.8}N and having a thickness of 3 nm and 100 layers each containing GaN and having a thickness of 3 nm are alternately stacked.

Note that, the configuration of the p-type cladding layer is not limited thereto, and the p-type cladding layer may include layers each containing AlₓGa₁₋ₓN (0<x<1) and having a thickness ranging from 0.3 μm to 1 μm inclusive. In addition, the p-type cladding layer is not the superlattice layer, and may be a bulk cladding layer containing AlₓGa₁₋ₓN (0<x<1). In addition, the p-type cladding layer may have a structure including a layer containing a plurality of AlₓGa₁₋ₓN (0≤x<1) having different Al compositions.

In addition, the p-type cladding layer may be another material other than AlGaN having a refractive index suitable for confining light in active layer 53. For example, the p-type cladding layer may be formed of an ITO film, a transparent dielectric oxide film which is a layer having less light absorption with respect to a laser oscillation wavelength, such as In₂O₃, Ga₂O₃, SnO, or InGaO₃, or the like. In addition, an p-type AlₓIn_{y}Ga_{1-x-y}N (0≤x+y≤1) guide layer or an undoped AlₓIn_{y}Ga_{1-x-y}N (0≤x+y≤1) guide layer may be provided on the p-type cladding layer.

Contact layer 55 is a semiconductor layer of a second conductivity type that is in ohmic contact with second electrode 57. For example, contact layer 55 is a p-type semiconductor layer, and is a layer having a thickness of 10 nm and containing p-GaN.

Contact layer 55 may be, for example, a layer made of p-InₓGa₁₋ₓN (0<x<1). Note that, the configuration of contact layer 55 is not limited thereto. A thickness of contact layer 55 may be more than or equal to 5 nm.

One or more ridge portions are formed in second semiconductor layer 54 and contact layer 55. A region of active layer 53 corresponding to each ridge portion (that is, a region of active layer 53 positioned below each ridge portion) serves as a luminous point that emits a laser beam. Note that, semiconductor laser element 2 has a plurality of ridge portions, and a plurality of active layers corresponding to the plurality of ridge portions serve as luminous points, and the laser beams are emitted from the luminous points.

First electrode 56 is an electrode disposed on a lower principal surface of substrate 51 (that is, a principal surface on which first semiconductor layer 52 and the like are not disposed). In the present exemplary embodiment, first electrode 56 is a stack film in which Ti, Pt, and Au are sequentially stacked from substrate 51 side. The configuration of first electrode 56 is not limited thereto. First electrode 56 may be a stack film in which Ti and Au are stacked.

Second electrode 57 is an electrode disposed on contact layer 55. For example, second electrode 57 includes a p-side electrode in ohmic contact with contact layer 55, and a pad electrode disposed on the p-side electrode. The p-side electrode is a stack film in which Pd and Pt are sequentially stacked from contact layer 55 side. The configuration of the p-side electrode is not limited thereto. The p-side electrode may be a single-layer film or a multilayer film that is made of, for example, at least one of Cr, Ti, Ni, Pd, Pt, and Au. In addition, an ITO film which is a transparent oxide electrode, In₂O₃, Ga₂O₃, SnO, InGaO₃, or the like may be used.

The pad electrode is a pad-shaped electrode disposed above the p-side electrode. For example, the pad electrode is a stack film in which Ti and Au are sequentially stacked from the p-side electrode side, and is disposed in and around the ridge portion. The configuration of the pad electrode is not limited thereto, and for example, the pad electrode may be made of only Au, a stack film of Ti, Pt, and Au, or a stack film of Ni and Au. In addition, the pad electrode may be a stack film of another metal.

Note that, although not illustrated in FIG. 1, semiconductor stack body 50 may further include an insulating film, such as a SiO₂ film or a SiN film, covering a side wall of the ridge portion, and the like in addition to the above layers.

In addition, in the above description, an example in which the semiconductor stack body is made of a GaN-based material has been described, but the present exemplary embodiment is also applicable to a case where semiconductor stack body 50 is made of a GaAs-based material or an InP-based material.

In addition, semiconductor laser element 2 may be a single light emitting laser element.

### 1-1-2. Configuration Example of End Surface Protective Film 1F

End surface protective film 1F is disposed on resonator end surface 50F on the front side of semiconductor stack body 50. In other words, end surface protective film 1F is disposed on a laser beam emission side end surface of semiconductor stack body 50. End surface protective film 1F includes first dielectric layer 30 and second dielectric layer 40.

End surface protective film 1F protects resonator end surface 50F of the front side of semiconductor stack body 50 and reduces an end surface reflectivity of the laser beam in resonator end surface 50F. End surface protective film 1F may be referred to as, for example, an emission side protective layer.

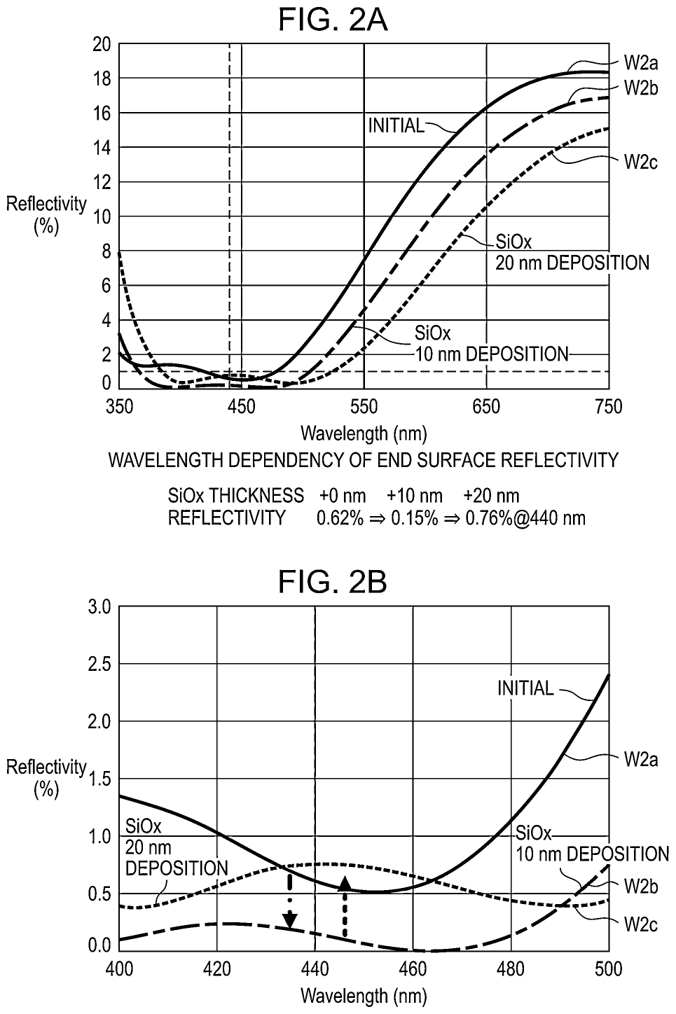

FIGS. 2A and 2B are graphs representing wavelength dependency of the end surface reflectivity of semiconductor laser element 2 according to the first exemplary embodiment. FIG. 2B is an enlarged graph of a portion having a wavelength of 400 nm to 500 nm in FIG. 2A.

The end surface reflectivity of end surface protective film 1F of semiconductor laser element 2 is set to be from 0.5% to 1.0% inclusive at a laser oscillation wavelength of 440 nm, for example, as indicated by initial waveform W2a of FIGS. 2A and 2B. For example, the end surface reflectivity at the laser oscillation wavelength in a state of semiconductor laser element 2 on which SiOₓ is not deposited on end surface protective film 1F is set to be from 0.5% to 1.0% inclusive. Hereinafter, the state of semiconductor laser element 2 on which SiOₓ is not deposited may be referred to as an initial state. The initial state is, for example, a state during shipment of semiconductor laser element 2.

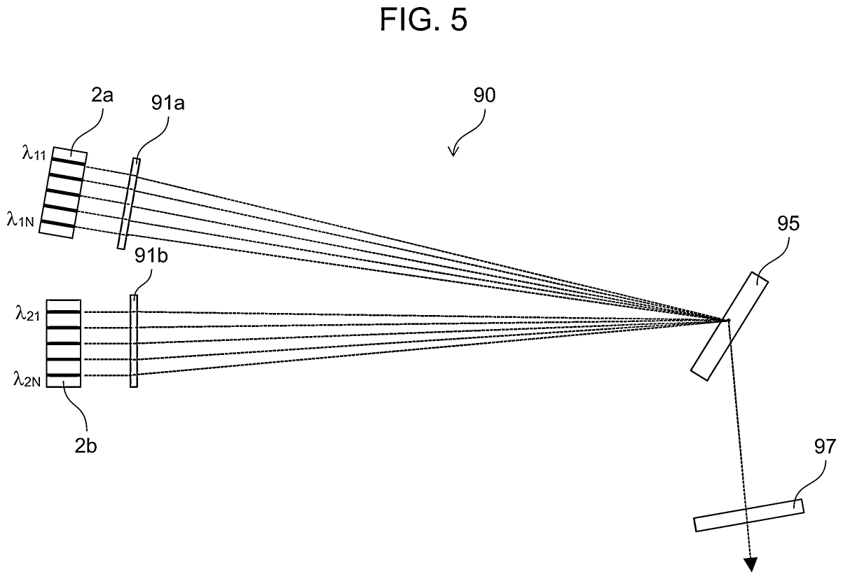

The laser device of the external resonator type includes semiconductor laser element 2 and a partial reflective mirror disposed outside end surface protective film 1F of semiconductor laser element 2. For example, laser device 90 of FIG. 5 includes semiconductor laser elements 2a, 2b and partial reflective mirror 97. The end surface reflectivity on the front side is set to be less than or equal to 1.0%, and thus, it is possible to realize external resonance characteristics with good resonance efficiency in the laser device of an external resonator type. Semiconductor laser element 2 can form an internal resonator between resonator end surface 50F and resonator end surface 50R (internal resonance mode). In addition, the laser device of the external resonator type can form an external resonator between resonator end surface 50R and partial reflective mirror 97 (see FIG. 5 to be described later). For example, internal resonance can be suppressed by reducing a reflectivity of light in end surface protective film 1F (to be less than or equal to 1.0%), and laser oscillation by the external resonator can be easily generated.

As described above, the end surface reflectivity on the front side of semiconductor laser element 2 is set to be less than or equal to 1.0%, and thus, the laser device of the external resonator type can improve external resonance efficiency and can stably emit a laser beam having high light intensity. That is, the end surface reflectivity on the front side is preferably a low reflectivity.

As described above, it is known that siloxane floating in the air undergoes a photochemical reaction by the laser beam in a wavelength band of blue-violet to green in a band of 390 nm to 530 nm. As illustrated in FIG. 1, it is known that SiOₓ is deposited around active layer 53 of a semiconductor laser element that outputs the laser beam in such a wavelength band and is not airtightly sealed.

The end surface reflectivity on the front side of semiconductor laser element 2 changes due to the deposition of SiOₓ. For example, in a case where the end surface reflectivity on the front side is set to be from 0.5% to 1.0% inclusive at a laser oscillation wavelength such as 440 nm, due to the deposition of SiOₓ caused by the operation of semiconductor laser element 2, the end surface reflectivity on the front side changes from initial waveform W2a of FIG. 2 to deposition waveform W2b, and further changes to deposition waveform W2c.

More specifically, at a laser oscillation wavelength of 440 nm, when SiOₓ is deposited by 10 nm from a state where SiOₓ is not deposited on end surface protective film 1F, the end surface reflectivity on the front side temporarily decreases as indicated by deposition waveform W2b from initial waveform W2a. Thereafter, when SiOₓ is further deposited and deposited by 20 nm, the end surface reflectivity on the front side at a laser oscillation wavelength of 440 nm increases as indicated by deposition waveform W2c. The end surface reflectivity on the front side changes in a range from 0% to 1.0% inclusive with respect to SiOₓ deposited by 20 nm or less in a bandwidth of 20 nm or more (for example, a center is 440 nm of the oscillation wavelength) including the oscillation wavelength of the laser beam.

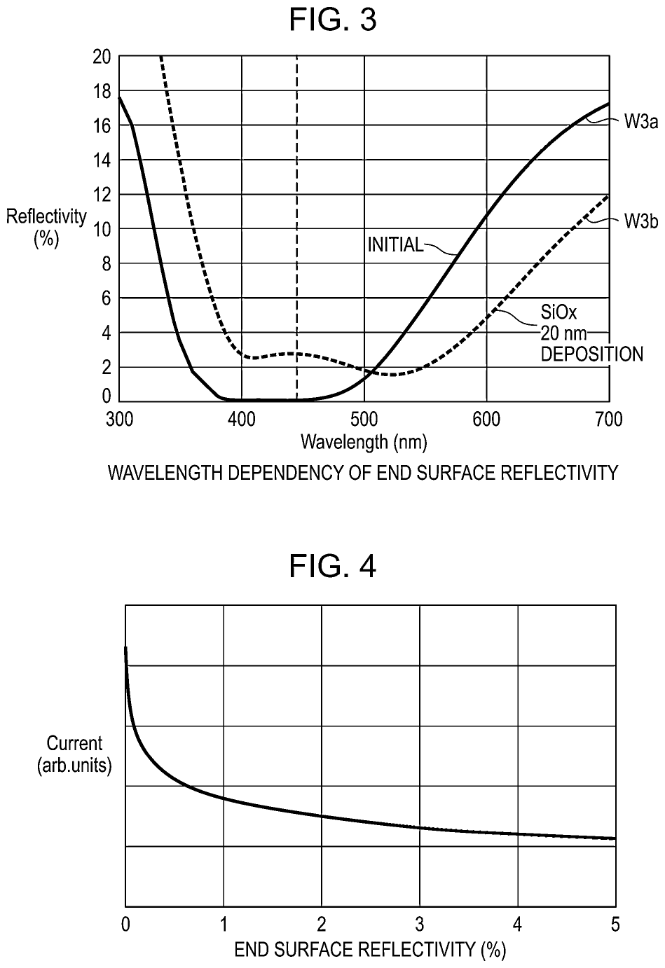

Here, as indicated by waveform W3a of FIG. 3, when the end surface reflectivity on the front side in the initial state of the semiconductor laser element is set to be the lowest, the end surface reflectivity at a laser oscillation wavelength of, for example, 440 nm greatly changes due to the deposition of SiO_{x.} For example, in a case where SiOₓ is deposited by 20 nm, the end surface reflectivity at a laser oscillation wavelength of 440 nm changes to exceed 2.0% as indicated by waveform W3b. Thus, in the laser device of the external resonator type, the efficiency of the external resonance characteristics is greatly reduced.

By contrast, in the present exemplary embodiment, as indicated by initial waveform W2a of FIGS. 2A and 2B, the end surface reflectivity at the laser oscillation wavelength of semiconductor laser element 2 in the initial state where SiOₓ is not deposited is not set to be a lowest end surface reflectivity, but is set to be slightly higher (offset is added). For example, the end surface reflectivity is set to be from 0.5% to 1.0% inclusive at which the efficiency of the external resonance increases.

That is, in the present exemplary embodiment, the end surface reflectivity at the laser oscillation wavelength of semiconductor laser element 2 in the initial state is set to be from 0.5%, which is more than a minimum end surface reflectivity, to 1.0% inclusive, at which the efficiency of the external resonance increases. Then, in the present exemplary embodiment, the low reflectivity of semiconductor laser element 2 over a long period of time is realized by using a state change such as a decrease and an increase in the end surface reflectivity at the laser oscillation wavelength caused by the deposition of SiOₓ in end surface protective film 1F on the front side.

For example, as indicated by an initial waveform W2a of FIG. 2, the end surface reflectivity in the initial state at a laser oscillation wavelength of 440 nm is set to be 0.62%. In a case where SiOₓ is deposited by 10 nm, the end surface reflectivity decreases to 0.15% as indicated by deposition waveform W2b. Then, in a case where SiOₓ is further increased and deposited by 20 nm, the end surface reflectivity is 0.76% as indicated by deposition waveform W2c. Even in a case where SiOₓ is deposited by 20 nm, the end surface reflectivity on the front side of semiconductor laser element 2 is suppressed to fall within 1.0%.

In the example of FIG. 3, in a case where SiOₓ is deposited by 20 nm, the end surface reflectivity exceeds 2.0%. By contrast, in the example of FIG. 2 according to the present exemplary embodiment, the end surface reflectivity is suppressed to fall within 1.0% as described above. In semiconductor laser element 2, since the change in the end surface reflectivity due to the deposition of SiOₓ is reduced, the laser device of the external resonator type using semiconductor laser element 2 can obtain stable external resonance characteristics.

Note that, in a GaN-based semiconductor laser in a wavelength band of blue-violet to green in a band of 390 nm to 530 nm, the change in the end surface reflectivity due to the deposition of SiOₓ occurs at any end surface reflectivity (even though the end surface reflectivity is high) regardless of the low end surface reflectivity.

FIG. 4 is a diagram illustrating an example of a relationship between the end surface reflectivity on the front side and an operating current value. As illustrated in FIG. 4, as the end surface reflectivity of semiconductor laser element 2 decreases, an operating current value of semiconductor laser element 2 increases. In addition, as illustrated in FIG. 4, at an end surface reflectivity of 1.0% or less, a change in the operating current value with respect to the end surface reflectivity increases. Accordingly, in the case of a low reflectivity structure, the change in the operating current value (that is, laser characteristics) becomes large with respect to a fluctuation in the reflectivity. On the other hand, for example, in the case of a standard reflectivity of about 5% to 18%, even though the reflectivity slightly changes, since the change in the operating current value is small and a curve is gentle, the change in the laser characteristics is small. Thus, the structure of the present disclosure that suppresses the reflectivity fluctuation has a higher effect at a low reflectivity.

### 1-1-2-1. Configuration Example of First Dielectric Layer of End Surface Protective Film 1F

First dielectric layer 30 is disposed on resonator end surface 50F on the front side. First dielectric layer 30 suppresses deterioration such as damage due to the laser beam in resonator end surface 50F of semiconductor stack body 50. First dielectric layer 30 may include at least one layer of a dielectric film including at least one of a nitride film and an oxynitride film. As a result, oxygen diffusion from resonator end surface 50F to a direction of semiconductor stack body 50 is reduced, and deterioration such as damage due to the laser beam on resonator end surface 50F of semiconductor stack body 50 can be suppressed. Accordingly, semiconductor laser element 2 can be operated for a long period of time.

First dielectric layer 30 is directly connected to resonator end surface 50F of semiconductor stack body 50. That is, first dielectric layer 30 is formed in contact with resonator end surface 50F. Thus, a nitride film or an oxynitride film having crystallinity similar to semiconductor stack body 50 is used as first dielectric layer 30, and thus, protection performance of resonator end surface 50F can be enhanced.

First dielectric layer 30 includes, for example, an AlON film. More specifically, first dielectric layer 30 is a single-layer film including an AlON film having a thickness of about 20 nm. Note that, the configuration of first dielectric layer 30 is not limited thereto. First dielectric layer 30 may be, for example, another oxynitride film such as SiON, or a nitride film such as an AlN film or a SiN film.

First dielectric film 30 may include a plurality of layers of two layers to four layers instead of one layer. Among the plurality of layers of first dielectric film 30, a layer directly connected to resonator end surface 50F may be a nitride film or an oxynitride film. For example, the layer directly connected to resonator end surface 50F may be an AlON film, a SiON film, an AlN film, or a SiN film. The layer not directly connected to resonator end surface 50F may not be a nitride film or an oxynitride film. Specifically, an AlON film, a SiON film, an AlN film, a SiN film, an Al₂O₃ film, or a SiO₂ film may be used.

### 1-1-2-2. Configuration Example of Second Dielectric Layer of End Surface Protective Film 1F

Second dielectric layer 40 is a dielectric layer stacked on the front side of first dielectric layer 30. Second dielectric layer 40 includes first layer 41, second layer 42, and third layer 43.

Second dielectric layer 40 is made of an oxide film, an oxynitride film, or a nitride film, and plays a role of adjusting the end surface reflectivity. Thus, second dielectric layer 40 is formed to obtain a desired reflectivity.

For example, as illustrated in FIGS. 2A and 2B, in order to realize an end surface reflectivity of 1.0% or less in a wavelength band in a wide range with respect to an oscillation wavelength of the laser beam, such as 440 nm, second dielectric layer 40 is formed by a plurality of layers.

Refractive index n2 of second layer 42 is set to be higher than refractive index n1 of first layer 41 and refractive index n3 of third layer 43 with respect to the wavelength of the laser beam emitted from resonator end surface 50F. As a result, it is possible to realize end surface protective film 1F having a reflectivity of 1.0% or less in a wide range, for example, a wavelength band of 50 nm or more with an oscillation wavelength of the laser beam of 440 nm as a center.

First layer 41 is, for example, an Al₂O₃ film having a thickness of about 100 nm. First layer 41 may have a dielectric film having a refractive index lower than second layer 42, and may include, for example, at least one of a SiO₂ film, an AlON film, and a SiON film. As a result, first layer 41 having a relatively low refractive index can be realized.

Second layer 42 is, for example, a ZrO₂ film having a thickness of about 50 nm. Second layer 42 may be a dielectric film having a refractive index higher than first layer 41 and third layer 43. Second layer 42 may include at least one of an AlN film, an AlON film, a SiN film, an SiON film, a TiO₂ film, an Nb₂O₅ film, a Ta₂O₅ film, and an HfO₂ film. As a result, second layer 42 having a relatively high refractive index can be realized.

Third layer 43 is, for example, an SiO₂ film having a thickness of about 100 nm. Third layer 43 may be a dielectric film having a refractive index lower than second layer 42, and may include, for example, at least one of an Al₂O₃ film, an AlON film, and a SiON film. As a result, third layer 43 having a relatively low refractive index can be realized.

In order to set the end surface reflectivity (the end surface reflectivity on the front side of semiconductor laser element 2) of end surface protective film 1F at the laser oscillation wavelength in the initial state to be from 0.5% to 1.0% inclusive, which is more than the minimum end surface reflectivity, the end surface reflectivity can be set by adjusting a film thickness or a film thickness ratio of the dielectric film used for first layer 41 and/or third layer 43 in second dielectric layer 40. For example, the end surface reflectivity can be set by increasing the film thickness of first layer 41 by several nm and decreasing the film thickness of third layer 43 by several nm.

Note that, as illustrated in FIGS. 2A and 2B, for example, the configuration of end surface protective film 1F is not limited as long as the end surface reflectivity at the laser oscillation wavelength falls within 1.0% by the deposition of SiOₓ by 20 nm.

In addition, in order to reduce stress applied to resonator end surface 50F, a strain relaxation layer of 1 nm to 20 nm may be inserted into end surface protective film 1F. Even in this case, the end surface reflectivity can be maintained within 1.0%, and the effect of suppressing the end surface reflectivity and the stress reduction effect can be obtained. For example, a thin film having a small thermal expansion coefficient and less light absorption at the laser oscillation wavelength, such as SiO₂, may be used as the strain relaxation layer. Of course, other dielectrics having less light absorption may be used for the strain relaxation layer, and a similar effect can be expected even in this case. In addition, the film thickness is preferably a thin film that does not influence the end surface reflectivity, and is preferably from about 1 nm to 20 nm inclusive.

### 1-1-3. Configuration Example of End Surface Protective Film 1R

End surface protective film 1R is disposed on resonator end surface 50R of the rear side of semiconductor stack body 50. In other words, end surface protective film 1R is disposed on a non-emission side end surface of semiconductor stack body 50 opposite to the laser beam emission side end surface. End surface protective film 1R has a function of protecting resonator end surface 50R of semiconductor stack body 50 and increasing the end surface reflectivity of the laser beam on resonator end surface 50R. For example, end surface protective film 1R may be referred to as a non-emission side protective layer.

End surface protective film 1R is, for example, a multilayer film in which a plurality of pairs of SiO₂ films and AlON films having a thickness of about λ/(4n) with a wavelength of the laser beam as λ are stacked. Here, n represents the refractive index of each dielectric film. As a result, the reflectivity of the laser beam in end surface protective film 1R can be set to be more than or equal to 90%, and semiconductor laser element 2 having high slope efficiency and a low threshold current is realized.

Note that, the configuration of end surface protective film 1R is not limited to the above configuration, and as long as a desired reflectivity can be obtained, a plurality of pairs of SiO₂ films and ZrO₂ films, SiO₂ films and Ta₂O₅ films, SiO₂ films and AlN films, SiO₂ films and SiN films, SiO₂ films and TiO₂ films, SiO₂ films and HfO₂ films, SiO₂ films and Nb₂O₅ films, SiO₂ films and Al₂O₃ films, and the like may be stacked.

In addition, Al₂O₃ films may be used as low refractive index films of the above pairs. In addition, similarly to end surface protective film 1F, end surface protective film 1R may also include at least one of a nitride film and an oxynitride film.

### 1-2. Actions and Effects of End Surface Protective Film 1F

Semiconductor stack body 50 is made of, for example, a gallium nitride-based material. In a case where semiconductor stack body 50 is made of a gallium nitride-based material, semiconductor laser element 2 can emit the laser beam in a wavelength range of, for example, from about 390 nm to 530 nm inclusive.

Since airtight sealing of semiconductor laser element 2 is not performed, the siloxane-derived SiOₓ may be deposited outside end surface protective film 1F during a laser operation, particularly in a blue-violet-based to green-based semiconductor laser element in a band of 390 nm to 530 nm. However, in the present exemplary embodiment, the end surface reflectivity of semiconductor laser element 2 at the laser oscillation wavelength in the initial state is set to be, for example, from 0.5% which is more than the minimum end surface reflectivity to 1.0% inclusive at which the efficiency of the external resonance increases. As a result, it is possible to reduce the change in the end surface reflectivity due to the deposition of SiOₓ on the outside of end surface protective film 1F. In addition, even though SiOₓ is deposited by, for example, 20 nm, the end surface reflectivity can be suppressed to be less than or equal to 1.0%, and stable external resonance characteristics can be realized in the laser device of the external resonator type.

The gallium nitride-based material may deteriorate due to oxygen diffusion from the end surface, but end surface protective film 1F reduces oxygen diffusion to resonator end surface 50F on the front side. Thus, the deterioration of semiconductor laser element 2 can be suppressed.

Note that, semiconductor laser element 2 is made of a gallium nitride-based material, and the laser beam emitted from semiconductor laser element 2 is the blue-violet-based to green-based laser beam having the wavelength in a band from about 390 nm to 530 nm inclusive, but is not limited thereto. For example, the present exemplary embodiment may be applied to a semiconductor laser element in which the semiconductor stack body is made of an AlGaInP-based material and which outputs a laser beam in a red wavelength band (band from 600 nm to 700 nm inclusive). In addition, the present disclosure may be applied to a semiconductor laser element in which the semiconductor stack body is made of a gallium arsenide material and which outputs a laser beam in an infrared wavelength band (band from 750 nm to 1100 nm inclusive). In addition, the present disclosure may be applied to a semiconductor laser element in which the semiconductor stack body is made of an InP-based material and which outputs a laser beam having a wavelength band of 1 μm.

The deposition of the siloxane-derived SiOₓ is large in the case of a gallium nitride-based material. Accordingly, the effect of the present exemplary embodiment is increased in semiconductor laser element 2 made of a gallium nitride-based material.

### 1-3. Manufacturing Method Example

Next, a method for manufacturing semiconductor laser element 2 according to the present exemplary embodiment will be described. First, semiconductor stack body 50 is formed. In forming semiconductor stack body 50, substrate 51 is first prepared, and first semiconductor layer 52, active layer 53, second semiconductor layer 54, and contact layer 55 are sequentially stacked. In the present exemplary embodiment, first semiconductor layer 52 as an n-type cladding layer, active layer 53, second semiconductor layer 54 as a p-type cladding layer, and contact layer 55 are sequentially stacked on substrate 51. Each layer can be formed by, for example, a metal organic chemical vapor deposition (MOCVD) method.

Subsequently, the ridge portion is formed in second semiconductor layer 54 and contact layer 55. The ridge portion can be formed, for example, by reactive ion etching of an inductive coupled plasma (ICP) or the like.

Through the above steps, semiconductor stack body 50 is formed.

Subsequently, an insulating film, such as a SiO₂ film, is formed, for example, by a plasma CVD method or the like. At least a part of an upper surface of the ridge portion of the insulating film is removed by wet etching or the like. At that time, the insulating film may be formed by a solid-source electron cyclotron resonance (ECR) sputter plasma forming apparatus or the like, or an insulating film such as a SiN film may be formed by a similar method.

Subsequently, second electrode 57 is formed on the ridge portion by, for example, a vacuum deposition method or the like.

Subsequently, first electrode 56 is formed on a lower surface of substrate 51 by, for example, a vacuum deposition method or the like.

Subsequently, in order to form resonator end surface 50F and resonator end surface 50R, for example, due to the use of a laser scribing apparatus and a breaking apparatus, primary cleavage of a semiconductor wafer is performed, the laser resonator end surface is formed, and the laser bar is created.

Subsequently, end surface protective film 1F and end surface protective film 1R are formed on resonator end surface 50F on the front side and resonator end surface 50R on the rear side of semiconductor stack body 50, respectively. For respectively forming the dielectric films on resonator end surface 50F and resonator end surface 50R, for example, a solid-source electron cyclotron resonance (ECR) sputtering plasma forming apparatus is used. As a result, damage to each end surface, possibly occurring when each dielectric film is formed, can be suppressed.

Through the above steps, semiconductor laser element 2 is manufactured.

### 1-4. Application Example

Next, an application example of semiconductor laser element 2 according to the present exemplary embodiment will be described. Semiconductor laser element 2 according to the present exemplary embodiment can be applied to, for example, laser device 90 of an external resonator type that performs wavelength synthesis. Hereinafter, laser device 90 to which semiconductor laser element 2 is applied will be described with reference to FIG. 5. FIG. 5 is a diagram illustrating a configuration example of laser device 90 including semiconductor laser element 2.

As illustrated in FIG. 5, laser device 90 includes semiconductor laser elements 2a, 2b, optical lenses 91a, 91b, diffraction grating 95, and partial reflective mirror 97.

Each of semiconductor laser elements 2a, 2b is semiconductor laser element 2 described above. Semiconductor laser elements 2a, 2b have N (N is an integer of 2 or more) luminous points E₁₁ to E_{1N} and N luminous points E₂₁ to E_{2N}, respectively. Each of these luminous points emits a laser beam. The wavelength of the laser beam emitted from each luminous point is determined by a wavelength selection action by an external resonator including diffraction grating 95 to be described later.

In semiconductor laser element 2a, luminous points E₁₁ to E_{1N}, respectively, emit laser beams having wavelengths λ₁₁ to λ_{1N} different from each other. In semiconductor laser element 2b, luminous points E₂₁ to E_{2N}, respectively, emit laser beams having wavelengths λ₂₁ to λ_{2N} different from each other. Semiconductor laser elements 2a, 2b are disposed such that the laser beams propagate in the same plane.

Each of optical lenses 91a, 91b is provided to correspond to each of semiconductor laser elements 2a, 2b. Optical lenses 91a, 91b are optical elements that converge the laser beams emitted from semiconductor laser elements 2a, 2b onto diffraction grating 95. Note that, each of optical lenses 91a, 91b may have a function of collimating each laser beam. In addition, laser device 90 may include a collimating lens that collimates each laser beam, separately from optical lenses 91a, 91b.

Diffraction grating 95 is a wavelength dispersion element that multiplexes a plurality of laser beams having different wavelengths from each other. Wavelengths and incident angles of a plurality of laser beams to be incident on diffraction grating 95 and intervals between slits of diffraction grating 95 are appropriately set, and thus, the plurality of laser beams in different propagation directions are synthesized on substantially the same optical axis.

Partial reflective mirror 97 is a mirror that forms an external resonator with end surface protective film 1R on the rear side of each of semiconductor laser elements 2a, 2b, and functions as an output coupler that emits a laser beam. A reflectivity and a transmittance of partial reflective mirror 97 may be appropriately set in accordance with gains or the like of semiconductor laser elements 2a, 2b.

An operation of laser device 90 will be described. Each of semiconductor laser elements 2a, 2b emits N laser beams when a current is supplied. The N laser beams emitted from semiconductor laser element 2a are converged on a convergence point on diffraction grating 95 by optical lens 91a. The N laser beams emitted from semiconductor laser element 2b are converged on a convergence point on diffraction grating 95 by optical lens 91b.

Each laser beam converged on diffraction grating 95 is diffracted by diffraction grating 95, and is directed toward partial reflective mirror 97 on substantially the same optical axis. A part of each laser beam directed to partial reflective mirror 97 is reflected by partial reflective mirror 97, returns to each of semiconductor laser elements 2a, 2b via diffraction grating 95 and optical lenses 91a, 91b, and is reflected by end surface protective film 1R on the rear side of each of semiconductor laser elements 2a, 2b.

As described above, the external resonator is formed between end surface protective film 1R on the rear side of each of semiconductor laser elements 2a, 2b and partial reflective mirror 97.

On the other hand, the laser beam transmitted through partial reflective mirror 97 becomes output light of laser device 90. The output light of laser device 90 becomes a high-power laser beam by, for example, an optical fiber arranged on an optical axis of the output light.

In laser device 90 of the external resonator type, it is important to suppress internal resonance in each of semiconductor laser elements 2a, 2b. In order to suppress the internal resonance in each of semiconductor laser elements 2a, 2b, as described above, reflection of light on end surface protective film 1F on the front side of each of semiconductor laser elements 2a, 2b may be reduced as much as possible. Thus, the reflectivity of end surface protective film 1F disposed on resonator end surface 50F on the front side is preferably less than or equal to 1.0%.

Examples of the method for synthesizing beams include a wavelength synthesis method to be used in laser device 90 illustrated in FIG. 5 and a spatial synthesis method for spatially synthesizing light rays. In order to realize the narrowing of the beam, the wavelength synthesis method for condensing light rays having different wavelengths on the same optical axis is preferable rather than the spatial synthesis method.

As illustrated in FIG. 5, the laser beam having wavelength 211 and the laser beam having wavelength λ_{1N} of semiconductor laser element 2a have different optical path lengths and different incident angles with respect to diffraction grating 95. In semiconductor laser element 2b disposed at a position different from semiconductor laser element 2a, the laser beam having wavelength λ₂₁ and the laser beam having wavelength λ_{2N} also have different optical path lengths and different incident angles with respect to diffraction grating 95. A plurality of laser beams of wavelengths having different incident angles are synthesized, and thus, an optical power of the laser beam output from laser device 90 is increased. In order to further increase an optical power of laser device 90, for example, a laser beam having more wavelengths (more semiconductor laser elements 2) is prepared. In addition, each of semiconductor laser elements 2a, 2b has a plurality of luminous points. Each of the plurality of luminous points emits the laser beam.

As a result, a small laser beam source capable of emitting a plurality of laser beams is realized. In addition, in laser device 90 of the external resonator type that performs wavelength synthesis, small laser device 90 is realized by using semiconductor laser elements 2a, 2b.

Note that, in the present exemplary embodiment, the example in which laser device 90 includes two semiconductor laser elements 2a, 2b has been described, but the number of semiconductor laser elements included in laser device 90 is not limited thereto, and may be three or more. As the number of semiconductor laser elements 2 is increased, the optical power of laser device 90 can be increased.

In addition, a plurality of laser devices 90 that perform wavelength synthesis may be used to synthesize beams by the spatial synthesis method. Thus, the optical power of the laser beam can be increased.

In addition, in laser device 90, each of semiconductor laser elements 2a, 2b has a plurality of luminous points, but each of semiconductor laser elements 2a, 2b may have a single luminous point. According to the present exemplary embodiment, even in the semiconductor laser element having the single luminous point, it is possible to improve the optical power.

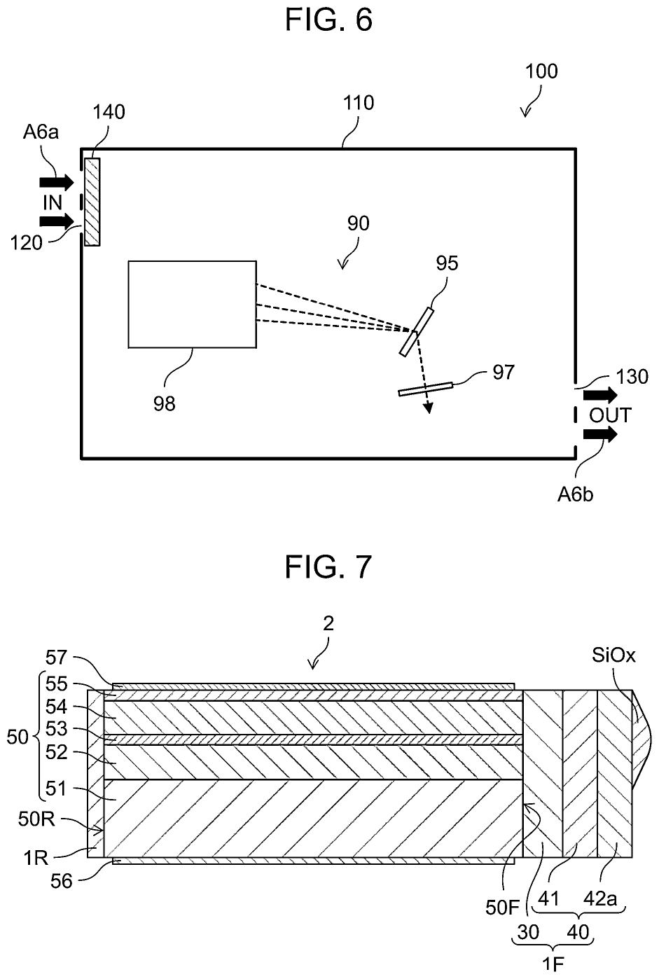

Next, an optical system including semiconductor laser element 2 will be described with reference to FIG. 6. FIG. 6 is a diagram illustrating a configuration example of the optical system including semiconductor laser element 2. As illustrated in FIG. 6, optical system 100 includes laser device 90. Laser device 90 includes a plurality of semiconductor laser elements 2 (not illustrated) and an optical lens (not illustrated), and includes unit 98 that outputs a laser beam, diffraction grating 95, and partial reflective mirror 97. Optical system 100 synthesizes a plurality of laser beams output from unit 98 and outputs the synthesized laser beam. Optical system 100 is, for example, a laser processing device of an external resonance type.

Optical system 100 has accommodation unit 110 that accommodates laser device 90. Accommodation unit 110 includes intake unit 120, exhaust unit 130, and siloxane adsorption filter 140.

Accommodation unit 110 is a hollow housing and accommodates laser device 90. Accommodation unit 110 includes intake unit 120 and exhaust unit 130. Arrows A6a and A6b illustrated in FIG. 6 respectively indicate flows of a supply gas and an exhaust gas. The gas is taken in from intake unit 120 and is exhausted from exhaust unit 130. The gas may be circulated.

An internal space of accommodation unit 110 is filled with, for example, the atmosphere and contains at least one of oxygen, hydrogen, argon, and a halogen-based gas. The internal space may be filled with dry air from which moisture has been removed from the atmosphere.

Siloxane adsorption filter 140 is provided in intake unit 120 of accommodation unit 110. Siloxane adsorption filter 140 adsorbs (reduces) siloxane contained in the gas taken in from intake unit 120.

As described above, the internal space of accommodation unit 110 may be filled with, for example, the atmosphere and may contain siloxane. SiOₓ may be deposited on end surface protective film 1F of semiconductor laser element 2 during the operation of laser device 90 in accommodation unit 110 due to siloxane contained in the atmosphere. Therefore, optical system 100 includes siloxane adsorption filter 140 in intake unit 120 of accommodation unit 110, and reduces the siloxane contained in the gas introduced from an outside. As a result, the deposition of SiOₓ on end surface protective film 1F of semiconductor laser element 2 can be suppressed.

### 1-5. Summary of First Exemplary Embodiment

As described above, semiconductor laser element 2 includes semiconductor stack body 50 that emits the laser beam, end surface protective film 1F disposed on the laser beam emission side end surface of semiconductor stack body 50, and end surface protective film 1R disposed on the non-emission side end surface opposite to the laser beam emission side end surface of semiconductor stack body 50 and reflecting the laser beam. The reflectivity of end surface protective film 1F at the oscillation wavelength of the laser beam is set to be higher than the reflectivity after the oxide containing silicon adheres to the first end surface (end surface on the front side) of end surface protective film 1F from which the laser beam is emitted. For example, the reflectivity of end surface protective film 1F at the oscillation wavelength of the laser beam is set to be more than or equal to 0.5%.

As a result, since the reflectivity at the oscillation wavelength of the laser beam in end surface protective film 1F decreases as SiOₓ adheres and is deposited, and then begins to increase, semiconductor laser element 2 can maintain a low reflectivity for a long period of time. For example, since semiconductor laser element 2 includes a step in which the change in the reflectivity decreases and increases, a reflectivity less than or equal to the reflectivity set in the initial state can be maintained for a long period of time.

In addition, since semiconductor laser element 2 can maintain a low reflectivity for a long period of time, it is possible to suppress a variation in the reflectivity at a low reflectivity.

In addition, the reflectivity of end surface protective film 1F at the oscillation wavelength of the laser beam is set to be less than or equal to 1.0%. As a result, in laser device 90 of the external resonator type using semiconductor laser element 2, a decrease in oscillation efficiency can be suppressed.

In addition, the end surface reflectivity of the initial structure is set to be more than or equal to 0.5%, and thus, it is possible to suppress variation in laser characteristics at a low reflectivity (less than or equal to 0.5%), to stabilize the laser characteristics, and to facilitate defective product selection. As a result, it is possible to provide semiconductor laser element 2 having a high optical power at low cost.

### Second Exemplary Embodiment

Hereinafter, a semiconductor laser element according to a second exemplary embodiment will be described. In the second exemplary embodiment, a case where a wavelength bandwidth of a bottom portion of the end surface reflectivity on the front side (a bottom portion of a concave-shaped waveform indicating the wavelength dependency of the end surface reflectivity) at the laser oscillation wavelength is narrower than the bandwidth of the first exemplary embodiment (in the case of a narrow band) will be described. Hereinafter, the description of the same contents as the first exemplary embodiment may be omitted.

### 2-1. Overall Configuration Example

FIG. 7 is a schematic sectional view illustrating a configuration example of semiconductor laser element 2 according to a second exemplary embodiment. FIG. 7 illustrates a section along a stacking direction (vertical direction in FIG. 7) of semiconductor stack body 50 included in semiconductor laser element 2 and a resonance direction (horizontal direction in FIG. 7) of a laser beam. As illustrated in FIG. 7, semiconductor laser element 2 includes semiconductor stack body 50, end surface protective film 1F, end surface protective film 1R, first electrode 56, and second electrode 57.

### 2-1-1. Configuration Examples of Semiconductor Stack Body and Electrode

Semiconductor stack body 50 illustrated in FIG. 7 is similar to semiconductor stack body 50 described in the first exemplary embodiment, and thus, the description thereof will be omitted.

### 2-1-2. Configuration Example of End Surface Protective Film 1F

End surface protective film 1F is disposed on resonator end surface 50F on the front side of semiconductor stack body 50. End surface protective film 1F includes first dielectric layer 30 and second dielectric layer 40.

End surface protective film 1F protects resonator end surface 50F on the front side of semiconductor stack body 50 and reduces the reflectivity of the laser beam in resonator end surface 50F.

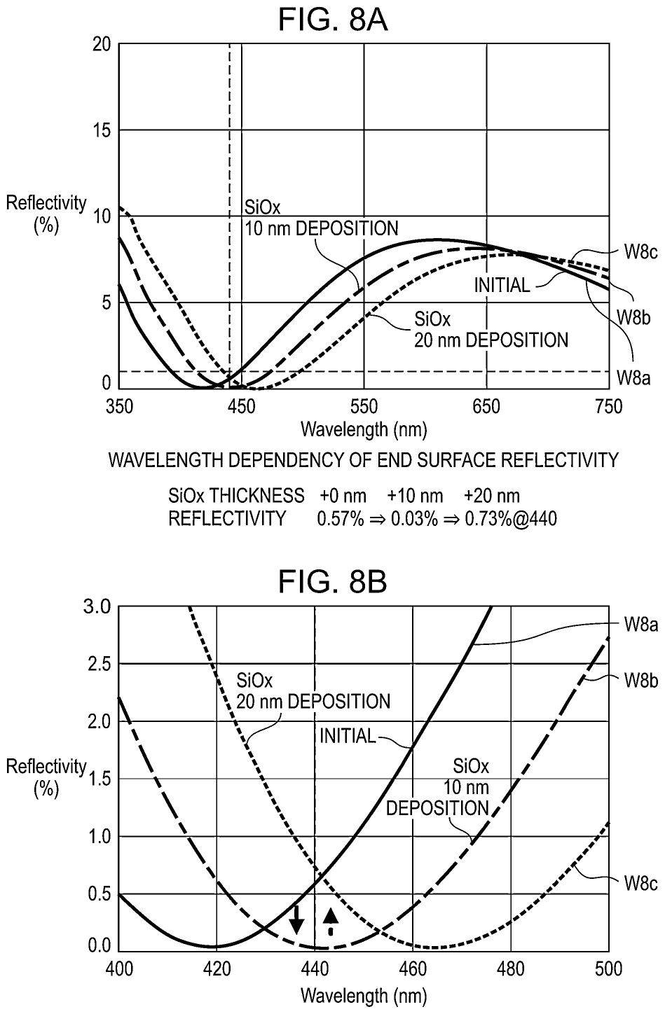

FIGS. 8A and 8B are graphs representing the wavelength dependency of the end surface reflectivity of semiconductor laser element 2 according to the second exemplary embodiment. FIG. 8B is an enlarged graph of a portion having a wavelength of 400 nm to 500 nm in FIG. 8A.

As illustrated in FIGS. 8A and 8B, the end surface reflectivity has a low reflectivity bandwidth that is a bandwidth of a bottom (valley) of the end surface reflectivity. The low reflectivity bandwidth at the laser oscillation wavelength of semiconductor laser element 2 according to the second exemplary embodiment is narrower than the low reflectivity bandwidth of semiconductor laser element 2 according to the first exemplary embodiment illustrated in FIGS. 2A and 2B. The reason why the low reflectivity bandwidth of semiconductor laser element 2 according to the first exemplary embodiment is wider than the low reflectivity bandwidth of semiconductor laser element 2 according to the second exemplary embodiment is that semiconductor laser element 2 according to the first exemplary embodiment includes second layer 42. Second layer 42 has a refractive index higher than refractive index n1 of first layer 41 and refractive index n3 of third layer 43 at the wavelength of the laser beam emitted from resonator end surface 50F.

The end surface reflectivity of end surface protective film 1F of semiconductor laser element 2 is set to be from 0.5% to 1.0% inclusive at a laser oscillation wavelength of 440 nm, for example, as indicated by initial waveform W8a of FIGS. 8A and 8B. For example, the end surface reflectivity at the laser oscillation wavelength in a state of semiconductor laser element 2 on which SiOₓ is not deposited on end surface protective film 1F is set to be from 0.5% to 1.0% inclusive.

The end surface reflectivity on the front side is set to be less than or equal to 1.0%, and thus, it is possible to realize the external resonance characteristics with good resonance efficiency in laser device 90 of the external resonator type illustrated in FIG. 5. Semiconductor laser element 2 can form an internal resonator between resonator end surface 50F and resonator end surface 50R (internal resonance mode). In addition, the laser device of the external resonator type can form an external resonator between resonator end surface 50R and partial reflective mirror 97 (see FIG. 5 to be described later). For example, internal resonance can be suppressed by reducing a reflectivity of light in end surface protective film 1F (to be less than or equal to 1.0%), and laser oscillation by the external resonator can be easily generated.

As described above, the end surface reflectivity on the front side of semiconductor laser element 2 is set to be less than or equal to 1.0%, and thus, the laser device of the external resonator type can improve external resonance efficiency and can stably emit a laser beam having high light intensity. That is, the end surface reflectivity on the front side is preferably a low reflectivity.

As described above, it is known that siloxane floating in the air undergoes a photochemical reaction by the laser beam in a wavelength band of blue-violet to green in a band of 390 nm to 530 nm. As illustrated in FIG. 7, it is known that SiOₓ is deposited around active layer 53 of a semiconductor laser element that outputs the laser beam in such a wavelength band and is not airtightly sealed.

The end surface reflectivity on the front side of semiconductor laser element 2 changes due to the deposition of SiOₓ. For example, in a case where the end surface reflectivity on the front side is set to be from 0.5% to 1.0% inclusive at a laser oscillation wavelength such as 440 nm, due to the deposition of SiOₓ caused by the operation of semiconductor laser element 2, the end surface reflectivity on the front side changes from initial waveform W8a of FIGS. 8A and 8B to deposition waveform W8b, and further changes to deposition waveform W8c.

More specifically, at a laser oscillation wavelength of 440 nm, when SiOₓ is deposited by 10 nm from a state where SiOₓ is not deposited on end surface protective film 1F, the end surface reflectivity on the front side temporarily decreases as indicated by deposition waveform W8b from initial waveform W8a. Thereafter, when SiOₓ is further deposited and deposited by 20 nm, the end surface reflectivity on the front side at a laser oscillation wavelength of 440 nm increases as indicated by deposition waveform W8c. The end surface reflectivity on the front side changes in a range from 0% to 1.0% inclusive with respect to SiOₓ deposited by 20 nm or less in a bandwidth of 20 nm or more (for example, a center is 440 nm of the oscillation wavelength) including the oscillation wavelength of the laser beam.

Here, as indicated by waveform W3a of FIG. 3, when the end surface reflectivity on the front side in the initial state of the semiconductor laser element is set to be the lowest, the end surface reflectivity at a laser oscillation wavelength of, for example, 440 nm greatly changes due to the deposition of SiOx. For example, in a case where SiOx is deposited by 20 nm, the end surface reflectivity at a laser oscillation wavelength of 440 nm changes to exceed 2.0% as indicated by waveform W3b. Thus, in the laser device of the external resonator type, the efficiency of the external resonance characteristics is greatly reduced.

By contrast, in the present exemplary embodiment, as indicated by initial waveform W8a of FIGS. 8A and 8B, the end surface reflectivity at the laser oscillation wavelength of semiconductor laser element 2 in the initial state where SiOx is not deposited is not set to be a lowest end surface reflectivity, but is set to be, for example, from 0.5% to 1.0% inclusive at which the efficiency of the external resonance increases.

That is, in the present exemplary embodiment, the end surface reflectivity at the laser oscillation wavelength of semiconductor laser element 2 in the initial state is set to be from 0.5%, which is more than a minimum end surface reflectivity, to 1.0% inclusive, at which the efficiency of the external resonance increases. Then, in the present exemplary embodiment, the low reflectivity of semiconductor laser element 2 over a long period of time is realized by using a state change such as a decrease and an increase in the end surface reflectivity at the laser oscillation wavelength caused by the deposition of SiOx in end surface protective film 1F on the front side.

For example, as indicated by initial waveform W8a of FIGS. 8A and 8B, the end surface reflectivity in the initial state at a laser oscillation wavelength of 440 nm is set to be 0.57%. In a case where SiOₓ is deposited by 10 nm, the end surface reflectivity decreases to 0.03% as indicated by deposition waveform W8b. Then, in a case where SiOₓ is further increased and deposited by 20 nm, the end surface reflectivity is 0.73% as indicated by deposition waveform W8c. Even in a case where SiOₓ is deposited by 20 nm, the end surface reflectivity on the front side of semiconductor laser element 2 is suppressed to fall within 1.0%.

In the example of FIG. 3, in a case where SiOₓ is deposited by 20 nm, the end surface reflectivity exceeds 2.0%. By contrast, in the examples of FIGS. 8A and 8B according to the present exemplary embodiment, the end surface reflectivity is suppressed to fall within 1.0% as described above. In semiconductor laser element 2, since the change in the end surface reflectivity due to the deposition of SiOₓ is reduced, the laser device of the external resonator type using semiconductor laser element 2 can obtain stable external resonance characteristics.

Note that, in a GaN-based semiconductor laser in a wavelength band of blue-violet to green in a band of 390 nm to 530 nm, the change in the end surface reflectivity due to the deposition of SiOₓ occurs at any end surface reflectivity (even though the end surface reflectivity is high) regardless of the low end surface reflectivity.

As illustrated in FIG. 4, as the end surface reflectivity of semiconductor laser element 2 decreases, the operating current value of semiconductor laser element 2 increases. In addition, as illustrated in FIG. 4, at an end surface reflectivity of 1.0% or less, a change in the operating current value with respect to the end surface reflectivity increases. Accordingly, in the case of a low reflectivity structure, the change in the operating current value (that is, laser characteristics) becomes large with respect to a fluctuation in the reflectivity. On the other hand, for example, in the case of a standard reflectivity of about 5% to 18%, even though the reflectivity slightly changes, since the change in the operating current value is small and a curve is gentle, the change in the laser characteristics is small. Thus, the structure of the present disclosure that suppresses the reflectivity fluctuation has a higher effect at a low reflectivity.

### 2-1-2-1. Configuration Example of First Dielectric Layer of End Surface Protective Film 1F

First dielectric layer 30 is disposed on resonator end surface 50F on the front side. First dielectric layer 30 suppresses deterioration such as damage due to the laser beam in resonator end surface 50F of semiconductor stack body 50.

First dielectric layer 30 includes at least two dielectric films. For example, first dielectric layer 30 includes a dielectric film made of at least one of a nitride film and an oxynitride film on resonator end surface 50F side. First dielectric layer 30 includes a dielectric film made of any of a nitride film, an oxynitride film, and an oxide film on second dielectric layer 40 side. As a result, oxygen diffusion from resonator end surface 50F to a direction of semiconductor stack body 50 is reduced, and deterioration such as damage due to the laser beam on resonator end surface 50F of semiconductor stack body 50 can be suppressed. Accordingly, semiconductor laser element 2 can be operated for a long period of time.

A nitride film or an oxynitride film having crystallinity similar to semiconductor stack body 50 is used for a first dielectric layer of first dielectric layer 30 directly connected to resonator end surface 50F on the front side. As a result, the protection performance of resonator end surface 50F can be enhanced.

A first layer of first dielectric layer 30 is made of, for example, an AlON film having a thickness of about 20 nm. Note that, the configuration of the first layer of first dielectric layer 30 is not limited thereto. The first layer of first dielectric layer 30 may be, for example, another oxynitride film such as SiON, or a nitride film such as an AlN film or a SiN film.

A dielectric film made of any of a nitride film, an oxynitride film, and an oxide film is used for a second dielectric layer of first dielectric layer 30. As a result, oxygen diffusion from resonator end surface 50F on the front side to a direction of semiconductor stack body 50 is reduced.

A second layer of first dielectric layer 30 is made of, for example, an Al₂O₃ film having a thickness of about 10 nm. Note that, the configuration of the second layer of first dielectric layer 30 is not limited thereto. The second layer of first dielectric layer 30 may be, for example, oxynitride film such as AlON or SiON, or a nitride film such as an AlN film or a SiN film.

The first dielectric film 30 may include a plurality of layers of three to four layers instead of two layers. Among the plurality of layers of first dielectric film 30, a layer directly connected to resonator end surface 50F may be a nitride film or an oxynitride film. For example, the layer directly connected to resonator end surface 50F may be an AlON film, a SiON film, an AlN film, or a SiN film. The other layer not directly connected to resonator end surface 50F may not be a nitride film or an oxynitride film. Specifically, an AlON film, a SiON film, an AlN film, a SiN film, an Al₂O₃ film, or a SiO₂ film may be used.

### 2-1-2-2. Configuration Example of Second Dielectric Layer of End Surface Protective Film 1F

Second dielectric layer 40 is a dielectric layer stacked on the front side of first dielectric layer 30. Second dielectric layer 40 includes first layer 41 and second layer 42a.

Second dielectric layer 40 is made of an oxide film, an oxynitride film, or a nitride film, and plays a role of adjusting the end surface reflectivity. Thus, second dielectric layer 40 is formed to obtain a desired reflectivity.

For example, as illustrated in FIGS. 8A and 8B, in order to realize an end surface reflectivity of 1.0% or less with respect to the oscillation wavelength of the laser beam such as 440 nm, for example, a film thickness and a film thickness ratio of second dielectric layer 40 are adjusted.

First layer 41 is, for example, an Al₂O₃ film having a thickness of about 100 nm. First layer 41 may be a dielectric film having less light absorption at an oscillation wavelength of the laser beam, and may be, for example, a SiO₂ film, an AlON film, a SiON film, an AlN film of a high refractive index film, an AlON film, a SiN film, a SiON film, a TiO₂ film, a Nb₂O₅ film, a Ta₂O₅ film, a ZrO₂ film, or an HfO₂ film.

Second layer 42a is a SiO₂ film having a thickness of about 100 nm. Third layer 43 may also be a dielectric having less light absorption at the oscillation wavelength of the laser beam, and may be, for example, an Al₂O₃ film, an AlON film, a SiON film, an AlN film of a high refractive index film, an AlON film, a SiN film, a SiON film, a TiO₂ film, a Nb₂O₅ film, a Ta₂O₅ film, a ZrO₂ film, or an HfO₂ film.

Although the example in which second dielectric layer 40 is a two-layer film has been described above, the present disclosure is not limited thereto. Second dielectric layer 40 may be a single layer as long as the end surface reflectivity is less than or equal to 1.0% at the oscillation wavelength of the laser beam. For example, second dielectric layer 40 may be an Al₂O₃ film having a thickness of about 50 nm, or may be a SiO₂ film without being limited to the Al₂O₃ film. In addition, second dielectric layer 40 may be an AlON film, an AlN film, an SiON film, a SiN film, a TiO₂ film, an Nb₂O₅ film, a ZrO₂ film, a Ta₂O₅ film, or an HfO₂ film. In semiconductor laser element 2 according to the second exemplary embodiment that may not have a broadband low reflectivity bandwidth like semiconductor laser element 2 according to the first exemplary embodiment, second dielectric layer 40 may not be a layer having a high refractive index, and may be constituted by a low refractive index layer.

In order to set the end surface reflectivity of end surface protective film 1F (the end surface reflectivity on the front side of semiconductor laser element 2) at the laser oscillation wavelength in the initial state to be from 0.5% to 1.0% inclusive, which is more than the minimum end surface reflectivity, the end surface reflectivity can be set by adjusting the film thickness or the film thickness ratio of the dielectric film used for first layer 41 and second layer 42a of second dielectric layer 40. For example, the end surface reflectivity can be set by decreasing the film thickness of second layer 42a by several nm.

Note that, as illustrated in FIGS. 8A and 8B, for example, the configuration of end surface protective film 1F is not limited as long as the end surface reflectivity at the laser oscillation wavelength falls within 1.0% by the deposition of SiOₓ by 20 nm.

In addition, in order to reduce stress applied to resonator end surface 50F, a strain relaxation layer of 1 nm to 20 nm may be inserted into end surface protective film 1F. Even in this case, the end surface reflectivity can be maintained within 1.0%, and the effect of suppressing the end surface reflectivity and the stress reduction effect can be obtained. For example, a thin film having a small thermal expansion coefficient and less light absorption at the laser oscillation wavelength, such as SiO₂, may be used as the strain relaxation layer. Of course, other dielectrics having less light absorption may be used for the strain relaxation layer, and a similar effect can be expected even in this case. In addition, the film thickness is preferably a thin film that does not influence the end surface reflectivity, and is preferably, for example, from about 1 nm to 20 nm inclusive.

### 2-1-3. Configuration Example of End Surface Protective Film 1R

End surface protective film 1R according to the second exemplary embodiment is similar to end surface protective film 1R according to the first exemplary embodiment, and the description thereof will be omitted.

### 2-2. Actions and Effects of End Surface Protective Film 1F

Although the configuration of second dielectric layer 40 of end surface protective film 1F is different between the first exemplary embodiment and the second exemplary embodiment, the effects are similar, and thus, the description thereof will be omitted.

### 2-3. Manufacturing Method Example and Application Example

Since an example of the method for manufacturing semiconductor laser element 2 and an application example are similar between the first exemplary embodiment and the second exemplary embodiment, the description thereof will be omitted.

### 2-4. Summary of Second Exemplary Embodiment

That is, effects similar to the first exemplary embodiment can also be achieved by the second exemplary embodiment. For example, as illustrated in FIG. 7, even in a case where end surface protective film 1F does not include second layer 42 described in the first exemplary embodiment and the wavelength bandwidth of the bottom portion of the end surface reflectivity on the front side is the narrow band, the effects similar to the first exemplary embodiment can be obtained.

### Third Exemplary Embodiment

Hereinafter, a semiconductor laser element according to a third exemplary embodiment will be described. In the first exemplary embodiment, although the example in which the end surface reflectivity of semiconductor laser element 2 having the broadband low reflectivity bandwidth at the laser oscillation wavelength is set to be from 0.5% to 1.0% inclusive has been described, in the third exemplary embodiment, an example in which the end surface reflectivity is set to be from 0.5% to 2.0% inclusive will be described. Hereinafter, the description of the same contents as the first exemplary embodiment may be omitted.

### 3-1. Configuration Example of End Surface Protective Film 1F

As illustrated in FIG. 1, end surface protective film 1F is disposed on resonator end surface 50F on the front side of semiconductor stack body 50. End surface protective film 1F includes first dielectric layer 30 and second dielectric layer 40.

End surface protective film 1F protects resonator end surface 50F of the front side of semiconductor stack body 50 and reduces an end surface reflectivity of the laser beam in resonator end surface 50F.

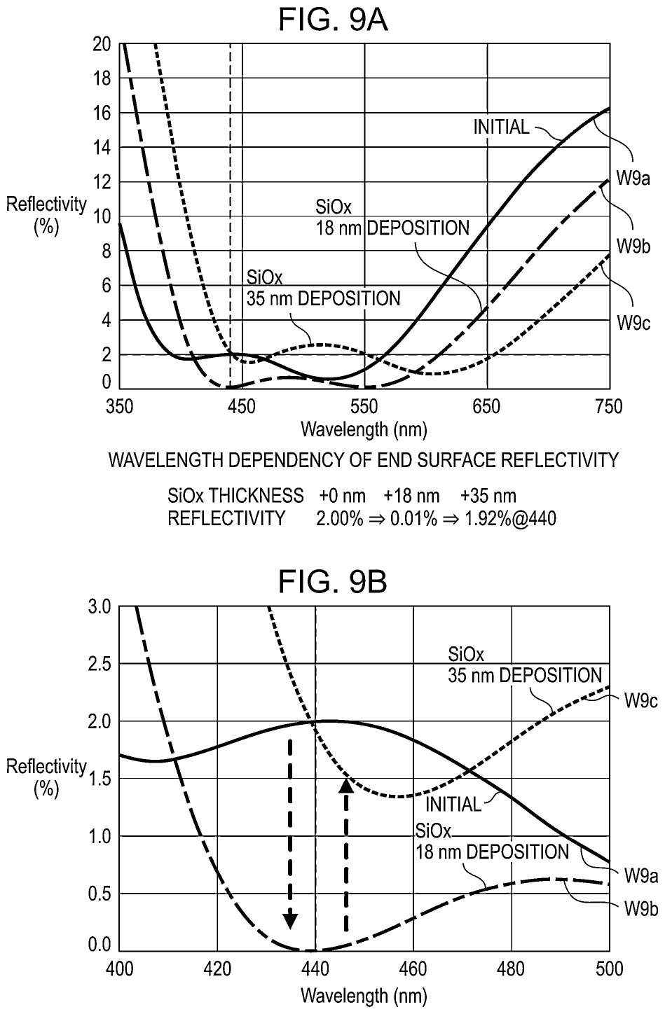

FIGS. 9A and 9B are graphs representing the wavelength dependency of the end surface reflectivity of semiconductor laser element 2 according to the third exemplary embodiment. FIG. 9B is an enlarged graph of a portion having a wavelength of 400 nm to 500 nm in FIG. 9A.

The end surface reflectivity of end surface protective film 1F of semiconductor laser element 2 is set to be from 0.5% to 2.0% inclusive at a laser oscillation wavelength of 440 nm, for example, as indicated by initial waveform W9a of FIGS. 9A and 9B. For example, the end surface reflectivity at the laser oscillation wavelength in a state where SiOₓ is not deposited on end surface protective film 1F of semiconductor laser element 2 is set to be from 0.5% to 2.0% inclusive.

The end surface reflectivity on the front side is set to be less than or equal to 2.0%, and thus, it is possible to realize the external resonance characteristics with good resonance efficiency in laser device 90 of the external resonator type illustrated in FIG. 5. Semiconductor laser element 2 can form an internal resonator between resonator end surface 50F and resonator end surface 50R (internal resonance mode). In addition, the laser device of the external resonator type can form an external resonator between resonator end surface 50R and partial reflective mirror 97 (see FIG. 5 to be described later). For example, the internal resonance can be suppressed by reducing the reflectivity of the light in end surface protective film 1F is reduced (to be less than or equal to 2.0%), and the laser oscillation by the external resonator can be easily generated.

As described above, the end surface reflectivity on the front side of semiconductor laser element 2 is set to be less than or equal to 2.0%, and thus, the laser device of the external resonator type can improve the external resonance efficiency and can stably emit a laser beam having high light intensity. That is, the end surface reflectivity on the front side is preferably a low reflectivity.

As described above, it is known that siloxane floating in the air undergoes a photochemical reaction by the laser beam in a wavelength band of blue-violet to green in a band of 390 nm to 530 nm. As illustrated in FIG. 1, it is known that SiOₓ is deposited around active layer 53 of a semiconductor laser element that outputs the laser beam in such a wavelength band and is not airtightly sealed.

The end surface reflectivity on the front side of semiconductor laser element 2 changes due to the deposition of SiOₓ. For example, in a case where the end surface reflectivity on the front side is set to be from 0.5% to 2.0% inclusive at a laser oscillation wavelength such as 440 nm, due to the deposition of SiOₓ caused by the operation of semiconductor laser element 2, the end surface reflectivity on the front side changes from initial waveform W9a of FIGS. 9A and 9B to deposition waveform W9b, and further changes to deposition waveform W9c.

More specifically, at a laser oscillation wavelength of 440 nm, when SiOₓ is deposited by 18 nm from a state where SiOₓ is not deposited on end surface protective film 1F, the end surface reflectivity on the front side temporarily decreases as indicated by initial waveform W9a to deposition waveform W9b. Thereafter, when SiOₓ is further deposited and deposited by 35 nm, the end surface reflectivity on the front side at a laser oscillation wavelength of 440 nm increases as indicated by deposition waveform W9c. The end surface reflectivity on the front side changes in a range from 0% to 2.0% inclusive with respect to SiOₓ deposited by 35 nm or less in a bandwidth of 40 nm (for example, oscillation wavelength 440 nm) including the oscillation wavelength of the laser beam.

Here, as indicated by waveform W3a of FIG. 3, when the end surface reflectivity on the front side in the initial state of the semiconductor laser element is set to be the lowest, the end surface reflectivity at a laser oscillation wavelength of, for example, 440 nm greatly changes due to the deposition of SiOₓ. For example, in a case where SiOₓ is deposited by 20 nm, the end surface reflectivity at a laser oscillation wavelength of 440 nm changes to exceed 2.0% as indicated by waveform W3b. Thus, in the laser device of the external resonator type, the efficiency of the external resonance characteristics is greatly reduced.

By contrast, in the present exemplary embodiment, as indicated by initial waveform W9a of FIGS. 9A and 9B, the end surface reflectivity at the laser oscillation wavelength of semiconductor laser element 2 in the initial state where SiOₓ is not deposited is not set to be a lowest end surface reflectivity, but is set to be, for example, from 0.5% to 2.0% inclusive at which the efficiency of the external resonance increases.

That is, in the present exemplary embodiment, the end surface reflectivity at the laser oscillation wavelength of semiconductor laser element 2 in the initial state is set to be from 0.5%, which is more than a minimum end surface reflectivity, to 2.0% inclusive, at which the efficiency of external resonance increases. Then, in the present exemplary embodiment, the low reflectivity of semiconductor laser element 2 over a long period of time is realized by using a state change such as a decrease and an increase in the end surface reflectivity at the laser oscillation wavelength caused by the deposition of SiOₓ in end surface protective film 1F on the front side.

For example, as indicated by initial waveform W9a of FIGS. 9A and 9B, the end surface reflectivity in the initial state at a laser oscillation wavelength of 440 nm is set to be 2.00%. In a case where SiOₓ is deposited by 18 nm, the end surface reflectivity decreases to 0.01% as indicated by deposition waveform W9b. Then, in a case where SiOₓ is further increased and deposited by 35 nm, the end surface reflectivity is 1.92% as indicated by deposition waveform W9c. Even in a case where SiOₓ is deposited by 35 nm, the end surface reflectivity on the front side of semiconductor laser element 2 is suppressed to fall within 2.0%.

In the example of FIG. 3, in a case where SiOₓ is deposited by 20 nm, the end surface reflectivity exceeds 2.0%. By contrast, in the examples of FIGS. 9A and 9B according to the present exemplary embodiment, the end surface reflectivity is suppressed to fall within 2.0% even in a case where SiOₓ is deposited by 35 nm as described above. In semiconductor laser element 2, since the change in the end surface reflectivity due to the deposition of SiOₓ is reduced, the laser device of the external resonator type using semiconductor laser element 2 can obtain stable external resonance characteristics.

In order to set the end surface reflectivity of end surface protective film 1F (the end surface reflectivity on the front side of semiconductor laser element 2) at the laser oscillation wavelength in the initial state to be from 0.5% to 2.0% inclusive, which is more than the minimum end surface reflectivity, the end surface reflectivity can be set by adjusting the film thickness or the film thickness ratio of the dielectric film used for first layer 41 and/or third layer 43 of second dielectric layer 40. For example, the end surface reflectivity can be set by increasing the film thickness of first layer 41 by several tens nm and decreasing the film thickness of third layer 43 by several nm.

Note that, as illustrated in FIGS. 9A and 9B, for example, the configuration of end surface protective film 1F is not limited as long as the end surface reflectivity at the laser oscillation wavelength falls within 2.0% by the deposition of SiOₓ by 35 nm.

### 3-2. Actions and Effects of End Surface Protective Film 1F

Semiconductor stack body 50 is made of, for example, a gallium nitride-based material. In a case where semiconductor stack body 50 is made of a gallium nitride-based material, semiconductor laser element 2 can emit the laser beam in a wavelength range of, for example, from about 390 nm to 530 nm inclusive.

Since airtight sealing of semiconductor laser element 2 is not performed, the siloxane-derived SiOₓ may be deposited outside end surface protective film 1F during a laser operation, particularly in a blue-violet-based to green-based semiconductor laser element in a band of 390 nm to 530 nm. However, in the present exemplary embodiment, the end surface reflectivity of semiconductor laser element 2 at the laser oscillation wavelength in the initial state is set to be, for example, from 0.5%, which is more than a minimum end surface reflectivity, to 2.0% inclusive, at which the efficiency of external resonance increases. As a result, it is possible to reduce the change in the end surface reflectivity due to the deposition of SiOₓ on the outside of end surface protective film 1F. In addition, even though SiOₓ is deposited by, for example, 35 nm, the end surface reflectivity can be suppressed to be less than or equal to 2.0%, and the stable external resonance characteristics can be realized in the laser device of the external resonator type.

The gallium nitride-based material may deteriorate due to oxygen diffusion from the end surface, but end surface protective film 1F reduces oxygen diffusion to resonator end surface 50F on the front side. Thus, the deterioration of semiconductor laser element 2 can be suppressed.

Note that, semiconductor laser element 2 is made of a gallium nitride-based material, and the laser beam emitted from semiconductor laser element 2 is the blue-violet-based to green-based laser beam having the wavelength in a band from about 390 nm to 530 nm inclusive, but is not limited thereto. For example, the present exemplary embodiment may be applied to a semiconductor laser element in which the semiconductor stack body is made of an AlGaInP-based material and which outputs a laser beam in a red wavelength band (band from 600 nm to 700 nm inclusive). In addition, the present disclosure may be applied to a semiconductor laser element in which the semiconductor stack body is made of a gallium arsenide material and which outputs a laser beam in an infrared wavelength band (band from 750 nm to 1100 nm inclusive). In addition, the present disclosure may be applied to a semiconductor laser element in which the semiconductor stack body is made of an InP-based material and which outputs a laser beam having a wavelength band of 1 μm.

The deposition of the siloxane-derived SiOₓ is large in the case of a gallium nitride-based material. Accordingly, the effect of the present exemplary embodiment is increased in semiconductor laser element 2 made of a gallium nitride-based material.

<Overall Configuration example>, <Configuration examples of semiconductor stack body and electrode>, <Configuration example of first dielectric layer of end surface protective film 1F>, <Configuration example of second dielectric layer of end surface protective film 1F>, <Configuration example of end surface protective film 1R>, <Manufacturing method>, and <Application example>according to the third exemplary embodiment are similar to <1-1. Overall configuration example>, <1-1-1. Configuration examples of semiconductor stack body and electrode>, <1-1-2-1. Configuration example of first dielectric layer of end surface protective film 1F>, <1-1-2-2. Configuration example of second dielectric layer of end surface protective film 1F>, <1-1-3 Configuration example of end surface protective film 1R>, <1-3 Manufacturing method>, and <1-4 Application example>described in the first exemplary embodiment, and the description thereof will be omitted.

### 3-3. Summary of Third Exemplary Embodiment

As described above, in semiconductor laser element 2 having a broadband low reflectivity bandwidth, the reflectivity at the oscillation wavelength of the laser beam in end surface protective film 1F is set to be from 0.5% to 2.0% inclusive. Thus, it is possible to obtain effects similar to the first exemplary embodiment.

In addition, since the laser characteristics can be maintained until the deposition of 35 nm as compared with the deposition of 20 nm (first exemplary embodiment), a longer laser operation time can be realized.

### Fourth Exemplary Embodiment

Hereinafter, a semiconductor laser element according to a fourth exemplary embodiment will be described. In the second exemplary embodiment, although the example in which the end surface reflectivity of semiconductor laser element 2 having the narrow band low reflectivity bandwidth at the laser oscillation wavelength is set to be from 0.5% to 1.0% inclusive has been described, in the fourth exemplary embodiment, an example in which the end surface reflectivity is set to be from 0.5% to 2.0% inclusive will be described. Hereinafter, the description of the same contents as the second exemplary embodiment may be omitted.

### 4-1. Configuration Example of End Surface Protective Film 1F

As illustrated in FIG. 7, end surface protective film 1F is disposed on resonator end surface 50F on the front side of semiconductor stack body 50. End surface protective film 1F includes first dielectric layer 30 and second dielectric layer 40.

End surface protective film 1F protects resonator end surface 50F on the front side of semiconductor stack body 50 and reduces the reflectivity of the laser beam in resonator end surface 50F.

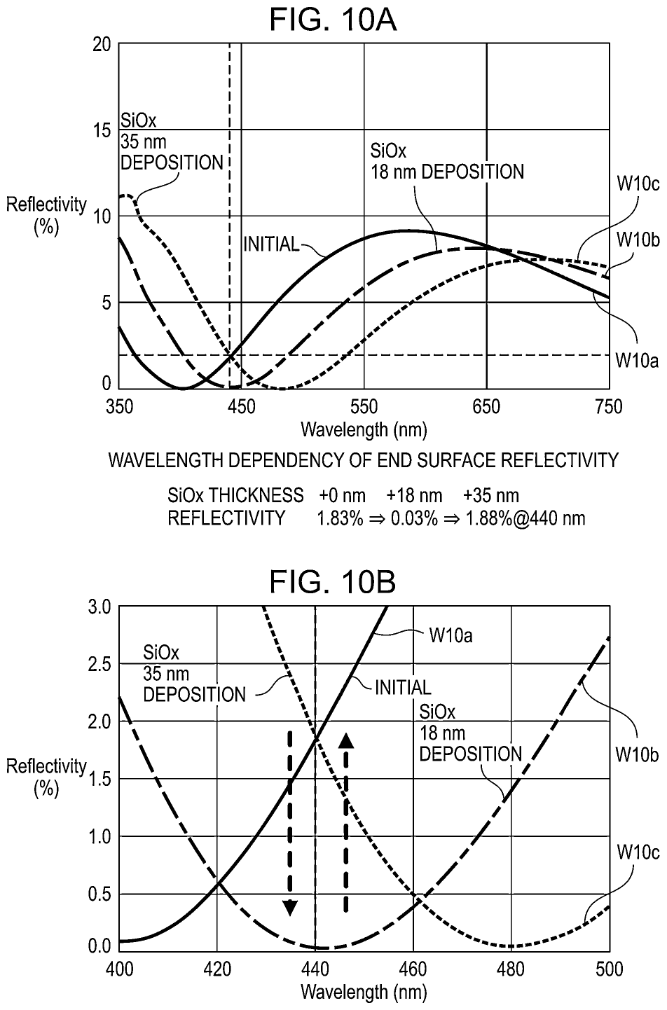

FIGS. 10A and 10B are graphs representing the wavelength dependency of the end surface reflectivity of semiconductor laser element 2 according to the fourth exemplary embodiment. FIG. 10B is an enlarged graph of a portion having a wavelength of 400 nm to 500 nm in FIG. 10A.

As illustrated in FIGS. 10A and 10B, the end surface reflectivity has a low reflectivity bandwidth that is a bandwidth of a bottom (valley) of the end surface reflectivity. The low reflectivity bandwidth at the laser oscillation wavelength of semiconductor laser element 2 according to the fourth exemplary embodiment is narrower than the low reflectivity bandwidth of semiconductor laser element 2 according to the third exemplary embodiment illustrated in FIGS. 9A and 9B. The reason why the low reflectivity bandwidth of semiconductor laser element 2 according to the third exemplary embodiment is wider than the low reflectivity bandwidth of semiconductor laser element 2 according to the fourth exemplary embodiment is that second layer 42 is provided. Second layer 42 has a refractive index higher than refractive index n1 of first layer 41 and refractive index n3 of third layer 43 at the wavelength of the laser beam emitted from resonator end surface 50F in semiconductor laser element 2 according to the third exemplary embodiment.

The end surface reflectivity of end surface protective film 1F of semiconductor laser element 2 is set to be from 0.5% to 2.0% inclusive at a laser oscillation wavelength of 440 nm, for example, as indicated by initial waveform W10a of FIGS. 10A and 10B. For example, the end surface reflectivity at the laser oscillation wavelength in a state where SiOₓ is not deposited on end surface protective film 1F of semiconductor laser element 2 is set to be from 0.5% to 2.0% inclusive.

The end surface reflectivity on the front side is set to be less than or equal to 2.0%, and thus, it is possible to realize the external resonance characteristics with good resonance efficiency in laser device 90 of the external resonator type illustrated in FIG. 5. Semiconductor laser element 2 can form an internal resonator between resonator end surface 50F and resonator end surface 50R (internal resonance mode). In addition, the laser device of the external resonator type can form an external resonator between resonator end surface 50R and partial reflective mirror 97 (see FIG. 5 to be described later). For example, the internal resonance can be suppressed by reducing the reflectivity of the light in end surface protective film 1F is reduced (to be less than or equal to 2.0%), and the laser oscillation by the external resonator can be easily generated.

As described above, the end surface reflectivity on the front side of semiconductor laser element 2 is set to be less than or equal to 2.0%, and thus, the laser device of the external resonator type can improve the external resonance efficiency and can stably emit a laser beam having high light intensity. That is, the end surface reflectivity on the front side is preferably a low reflectivity.

As described above, it is known that siloxane floating in the air undergoes a photochemical reaction by the laser beam in a wavelength band of blue-violet to green in a band of 390 nm to 530 nm. As illustrated in FIG. 7, it is known that SiOₓ is deposited around active layer 53 of a semiconductor laser element that outputs the laser beam in such a wavelength band and is not airtightly sealed.

The end surface reflectivity on the front side of semiconductor laser element 2 changes due to the deposition of SiOₓ. For example, in a case where the end surface reflectivity on the front side is set to be from 0.5% to 2.0% inclusive at a laser oscillation wavelength such as 440 nm, due to the deposition of SiOₓ caused by the operation of semiconductor laser element 2, the end surface reflectivity on the front side changes from initial waveform W10a of FIGS. 10A and 10B to deposition waveform W10b, and further changes to deposition waveform W10c.

More specifically, at a laser oscillation wavelength of 440 nm, when SiOₓ is deposited by 18 nm from a state where SiOₓ is not deposited on end surface protective film 1F, the end surface reflectivity on the front side temporarily decreases as indicated by initial waveform W10a to deposition waveform W10b. Thereafter, when SiOₓ is further deposited and deposited by 35 nm, the end surface reflectivity on the front side at a laser oscillation wavelength of 440 nm increases as indicated by deposition waveform W10c. The end surface reflectivity on the front side changes in a range from 0% to 2.0% inclusive with respect to SiOₓ deposited by 35 nm at the oscillation wavelength of the laser beam.

Here, as indicated by waveform W3a of FIG. 3, when the end surface reflectivity on the front side in the initial state of the semiconductor laser element is set to be the lowest, the end surface reflectivity at a laser oscillation wavelength of, for example, 440 nm greatly changes due to the deposition of SiOₓ. For example, in a case where SiOₓ is deposited by 20 nm, the end surface reflectivity at a laser oscillation wavelength of 440 nm changes to exceed 2.0% as indicated by waveform W3b. Thus, in the laser device of the external resonator type, the efficiency of the external resonance characteristics is greatly reduced.

By contrast, in the present exemplary embodiment, as indicated by initial waveform W10a of FIGS. 10A and 10B, the end surface reflectivity at the laser oscillation wavelength of semiconductor laser element 2 in the initial state where SiOₓ is not deposited is not set to be a lowest end surface reflectivity, but is set to be, for example, from 0.5% to 2.0% inclusive at which the efficiency of external resonance increases.

That is, in the present exemplary embodiment, the end surface reflectivity at the laser oscillation wavelength of semiconductor laser element 2 in the initial state is set to be from 0.5%, which is more than a minimum end surface reflectivity, to 2.0% inclusive, at which the efficiency of external resonance increases. Then, in the present exemplary embodiment, the low reflectivity of semiconductor laser element 2 over a long period of time is realized by using a state change such as a decrease and an increase in the end surface reflectivity at the laser oscillation wavelength caused by the deposition of SiOₓ in end surface protective film 1F on the front side.

For example, as indicated by initial waveform W10a of FIGS. 10A and 10B, the end surface reflectivity in the initial state at a laser oscillation wavelength of 440 nm is set to be 1.83%. In a case where SiOₓ is deposited by 18 nm, the end surface reflectivity decreases to 0.03% as indicated by deposition waveform W10b. Then, in a case where SiOₓ is further increased and deposited by 35 nm, the end surface reflectivity is 1.88% as indicated by deposition waveform W10c. Even in a case where SiOₓ is deposited by 35 nm, the end surface reflectivity on the front side of semiconductor laser element 2 is suppressed to fall within 2.0%.

In the example of FIG. 3, in a case where SiOₓ is deposited by 35 nm, the end surface reflectivity exceeds 2.0%. By contrast, in the examples of FIGS. 10A and 10B according to the present exemplary embodiment, the end surface reflectivity is suppressed to fall within 2.0% as described above. In semiconductor laser element 2, since the change in the end surface reflectivity due to the deposition of SiOₓ is reduced, the laser device of the external resonator type using semiconductor laser element 2 can obtain stable external resonance characteristics.

Note that, in a GaN-based semiconductor laser in a wavelength band of blue-violet to green in a band of 390 nm to 530 nm, the change in the end surface reflectivity due to the deposition of SiOₓ occurs at any end surface reflectivity (even though the end surface reflectivity is high) regardless of the low end surface reflectivity.

In order to set the end surface reflectivity of end surface protective film 1F (the end surface reflectivity on the front side of semiconductor laser element 2) at the laser oscillation wavelength in the initial state to be from 0.5% to 2.0% inclusive, which is more than the minimum end surface reflectivity, the end surface reflectivity can be set by adjusting the film thickness or the film thickness ratio of the dielectric film used for first layer 41 and second layer 42a of second dielectric layer 40. For example, the end surface reflectivity can be set by decreasing the film thickness of second layer 42a by several nm.

Note that, as illustrated in FIGS. 10A and 10B, for example, the configuration of end surface protective film 1F is not limited as long as the end surface reflectivity at the laser oscillation wavelength falls within 2.0% by the deposition of SiOₓ by 35 nm.

<Overall configuration example>, <Configuration examples of semiconductor stack body and electrode>, <Configuration example of first dielectric layer of end surface protective film 1F>, <Configuration example of second dielectric layer of end surface protective film 1F>, <Configuration example of end surface protective film 1R>, <Manufacturing method>, and <Application example>according to the fourth exemplary embodiment are similar to <2-1. Overall configuration example>, <2-1-1. Configuration examples of semiconductor stack body and electrode>, <2-1-2-1. Configuration example of first dielectric layer of end surface protective film 1F>, <2-1-2-2. Configuration example of second dielectric layer of end surface protective film 1F>, <2-1-3 Configuration example of end surface protective film 1R>, <2-3 Manufacturing method>, and <2-4 Application example>described in the second exemplary embodiment, and the description thereof will be omitted.

### 4-3. Summary of Fourth Exemplary Embodiment

As described above, in semiconductor laser element 2 having a narrow band low reflectivity bandwidth, the reflectivity at the oscillation wavelength of the laser beam in end surface protective film 1F is set to be from 0.5% or more and 2.0% inclusive. Thus, it is possible to obtain effects similar to the second exemplary embodiment.

In addition, since the laser characteristics can be maintained until the deposition of 35 nm as compared with the deposition of 20 nm (second exemplary embodiment), a longer laser operation time can be realized.

Although the exemplary embodiments have been described with reference to the accompanying drawings, the present disclosure is not limited to the examples. Those skilled in the art can clearly and easily conceive of various changes or modifications within the scope of claims. For example, numerical values, shapes, materials, components, arrangement positions of the components, connection forms of the components, and the like are merely examples and are not to limit the scope of the present disclosure. Such changes or modifications are also understood to belong to the technical scope of the present disclosure. In addition, within a range without departing from the gist of the present disclosure, the components in the exemplary embodiments may be combined as appropriate.

Although the case where the number of luminous points (emitters) is one and the case where the number of luminous points is two or more have been described as examples, the effects of the present disclosure do not depend on the number of emitters.

In order to protect the end surface of semiconductor stack body 50, any film, configuration, or combination of an oxide film, a nitride film, or an oxynitride film may be used for end surface protective film 1F on the front side and end surface protective film 1R on the rear side.

In each of the exemplary embodiments, although the example in which semiconductor stack body 50 is made of the gallium nitride-based material and outputs the laser beam near a wavelength band of 390 nm to 530 nm has been described, the present disclosure is not limited thereto. For example, each of the exemplary embodiments may be applied to a semiconductor laser element in which the semiconductor stack body is made of the AlGaInP-based material and which outputs the laser beam in the red wavelength band (band from 600 nm to 700 nm inclusive). In addition, each of the exemplary embodiments may be applied to a semiconductor laser element in which the semiconductor stack body is made of the gallium arsenide material and which outputs c laser beam in the infrared wavelength band (band from 750 nm to 1100 nm inclusive). In addition, each of the exemplary embodiments may be applied to a semiconductor laser element in which the semiconductor stack body is made of the InP-based material and which outputs the laser beam having a wavelength band of 1 μm.

Each of the end surface protective films may be formed by using a sputtering apparatus, a vapor deposition apparatus, or the like other than the solid-source ECR sputtering plasma forming apparatus, or may be formed by using: an ablation deposition apparatus using pulse laser deposition (PLD), atomic layer deposition (ALD), or the like; an epitaxial growth apparatus using MOCVD or the like; or the like.

In the laser device, the diffraction grating of the transmission type is used as the wavelength dispersion element, but the wavelength dispersion element is not limited thereto. As the wavelength dispersion element, for example, a prism, a diffraction grating of a reflection type, or the like may be used.

A substance to be deposited on end surface protective film 1F by laser emission may be an oxide containing silicon. The oxide containing silicon includes the above-described SiOₓ. SiOₓ may include, for example, SiO₂.

According to one embodiment of the present disclosure, the semiconductor laser element can maintain a low reflectivity for a long period of time.

Further advantages and effects in one embodiment of the present disclosure will be clarified from the specification and the drawings. Although such advantages and/or effects are provided by several exemplary embodiments and features described in the specification and drawings, all of them are not necessarily provided to obtain one or more identical features.

### INDUSTRIAL APPLICABILITY

The semiconductor laser element of the present disclosure can be used for light sources of, for example: industrial laser equipment such as industrial lighting, facility lighting, in-vehicle headlamps, and laser processing machines; and image displays such as laser displays and projectors, which require watt-class high power.

### REFERENCE MARKS IN THE DRAWINGS

1F, 1R: end surface protective film
30: first dielectric layer
40: second dielectric layer
41: first layer
42: second layer
43: third layer
50: semiconductor stack body
50F, 50R: resonator end surface

1. A semiconductor laser element comprising:
a semiconductor stack body that emits a laser beam;
an emission side protective layer that is disposed on a laser beam emission side end surface of the semiconductor stack body, and has a first end surface through which the laser beam travels; and
a non-emission side protective layer that is disposed on a non-emission side end surface of the semiconductor stack body opposite to the laser beam emission side end surface and reflects the laser beam,
wherein a reflectivity at an oscillation wavelength of the laser beam in the emission side protective layer before an oxide containing silicon adheres to the first end surface is higher than a reflectivity at an oscillation wavelength of the laser beam in the emission side protective layer after the oxide adheres to the first end surface.

2. The semiconductor laser element according to claim 1,
wherein, in the emission side protective layer, the reflectivity at the oscillation wavelength of the laser beam in the emission side protective layer decreases as the oxide adheres and is deposited, and then begins to increase.

3. The semiconductor laser element according to claim 1,
wherein the reflectivity at the oscillation wavelength of the laser beam in the emission side protective layer before the oxide adheres to the first end surface is more than or equal to 0.5%.

4. The semiconductor laser element according to claim 1,
wherein the reflectivity at the oscillation wavelength of the laser beam in the emission side protective layer before the oxide adheres to the first end surface is less than or equal to 1%.

5. The semiconductor laser element according to claim 4,
wherein, in the emission side protective layer, the reflectivity of the emission side protective layer changes in a range from 0% to 1% inclusive with respect to deposition of the oxide by 20 nm or less in a bandwidth of 20 nm or more including the oscillation wavelength of the laser beam.

6. The semiconductor laser element according to claim 1,
wherein the reflectivity at the oscillation wavelength of the laser beam in the emission side protective layer before the oxide adheres to the first end surface is less than or equal to 2%.

7. The semiconductor laser element according to claim 6,
wherein, in the emission side protective layer, the reflectivity of the emission side protective layer changes in a range from 0% to 2% inclusive with respect to the deposition of the oxide by 35 nm or less in a bandwidth of 40 nm or more including the oscillation wavelength of the laser beam.

8. The semiconductor laser element according to claim 1,
wherein the semiconductor stack body has a plurality of luminous points that emit the laser beam.

9. A laser device comprising:
a semiconductor laser element including:
a semiconductor stack body that emits a laser beam;
an emission side protective layer that is disposed on a laser beam emission side end surface of the semiconductor stack body and has a first end surface through which the laser beam travels; and
a non-emission side protective layer that is disposed on a non-emission side end surface of the semiconductor stack body opposite to the laser beam emission side end surface and reflects the laser beam,
wherein a reflectivity at an oscillation wavelength of the laser beam in the emission side protective layer before an oxide containing silicon adheres to the first end surface is higher than a reflectivity at an oscillation wavelength of the laser beam in the emission side protective layer after the oxide adheres to the first end surface,
an accommodation unit that includes an intake port and an exhaust port and accommodates the semiconductor laser element; and
a filter that adsorbs siloxane provided in the intake port.
